(19) United States
(12) Patent Application Publication
(10) Pub. No.: US 2026/0006900 A1
(43) Pub. Date: Jan. 1, 2026

(54) EXTENDED GATE AND STANDARD GATE INTEGRATION SCHEME

(71) Applicant: International Business Machines Corporation, Armonk, NY (US)

(72) Inventors: Ruqiang Bao, Niskayuna, NY (US); Anthony I-Chih Chou, Guilderland, NY (US); Tushar Gupta, Albany, NY (US)

(21) Appl. No.: 18/760,085

(22) Filed: Jul. 1, 2024

(51) Int. Cl. H01L 27/088; H01L 21/28; H01L 29/06; H01L 29/423; H01L 29/51; H01L 29/66; H01L 29/775; H01L 29/786

(52) U.S. Cl. CPC H10D 84/83; H01L 21/28238; H10D 64/518; H10D 64/685; H10D 64/693; H10D 30/014; H10D 30/43; H10D 30/6735; H10D 30/6757; H10D 62/121

(57) ABSTRACT

Embodiments of the invention include a semiconductor structure having a first transistor including first channel regions, a high-k dielectric layer on the first channel regions, and gate material on the high-k dielectric layer. A second transistor includes second channel regions, a nitride layer on the second channel regions, the high-k dielectric layer on the nitride layer, and the gate material on the high-k dielectric layer. The first and second channel regions include a corresponding number of semiconductor layers.

### BACKGROUND

The present invention generally relates to fabrication methods and resulting structures for integrated circuits (ICs), and more specifically, to fabrication methods and resulting structures configured and arranged for providing a nanosheet extended-gate transistor and standard-gate transistor integration scheme with a dog bone structure for scaling.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer, on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to providing a nanosheet extended gate transistor and standard gate transistor integration scheme with a dog bone structure for scaling. A non-limiting method of forming a semiconductor structure includes providing a first transistor having first channel regions, a high-k dielectric layer on the first channel regions, and gate material on the high-k dielectric layer. The method includes a second transistor comprising second channel regions, a nitride layer on the second channel regions, the high-k dielectric layer on the nitride layer, and the gate material on the high-k dielectric layer, where the first and second channel regions comprise a corresponding number of semiconductor layers.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A, 1B, 1C, 1D, 1E, and 1F respectively depict a top view and cross-sectional view of a portion of an integrated circuit (IC) under-fabrication after fabrication operations according to one or more embodiments of the invention;

FIGS. 2A, 2B, 2C, 2D, 2E, and 2F respectively depict a top view and a cross-sectional view of a portion of an IC under-fabrication after fabrication operations according to one or more embodiments of the invention;

FIGS. 3A, 3B, 3C, 3D, 3E, and 3F respectively depict a top view and a cross-sectional view of a portion of an IC under-fabrication after fabrication operations according to one or more embodiments of the invention;

FIGS. 4A, 4B, 4C, 4D, 4E, and 4F respectively depict a top view and a cross-sectional view of a portion of an IC under-fabrication after fabrication operations according to one or more embodiments of the invention;

FIGS. 5A, 5B, 5C, 5D, 5E, and 5F respectively depict a top view and a cross-sectional view of a portion of an IC under-fabrication after fabrication operations according to one or more embodiments of the invention;

FIGS. 6A, 6B, 6C, 6D, 6E, and 6F respectively depict a top view and cross-sectional views of a portion of an IC under-fabrication after fabrication operations according to one or more embodiments of the invention;

FIGS. 7A, 7B, 7C, 7D, 7E, and 7F respectively depict a top view and cross-sectional views of a portion of an IC under-fabrication after fabrication operations according to one or more embodiments of the invention;

FIGS. 8A, 8B, 8C, 8D, 8E, and 8F respectively depict a top view and cross-sectional views of a portion of an IC under-fabrication after fabrication operations according to one or more embodiments of the invention;

FIGS. 9A, 9B, 9C, 9D, 9E, and 9F respectively depict a top view and cross-sectional views of a portion of an IC under-fabrication after fabrication operations according to one or more embodiments of the invention;

FIGS. 10A, 10B, 10C, 10D, 10E, and 10F respectively depict a top view and cross-sectional views of a portion of an IC under-fabrication after fabrication operations according to one or more embodiments of the invention;

FIGS. 11A, 11B, 11C, 11D, 11E, and 11F respectively depict a top view and cross-sectional views of a portion of an IC under-fabrication after fabrication operations according to one or more embodiments of the invention;

FIGS. 12A, 12B, 12C, 12D, 12E, and 12F respectively depict a top view and cross-sectional view of a portion of an IC under-fabrication after fabrication operations according to one or more embodiments of the invention;

FIGS. 13A, 13B, 13C, 13D, 13E, and 13F respectively depict a top view and cross-sectional view of a portion of an IC under-fabrication after fabrication operations according to one or more embodiments of the invention;

FIGS. 14A, 14B, 14C, 14D, 14E, and 14F respectively depict a top view and cross-sectional view of a portion of an IC under-fabrication after fabrication operations according to one or more embodiments of the invention;

FIGS. 15A, 15B, 15C, 15D, 15E, and 15F respectively depict a top view and cross-sectional view of a portion of an IC under-fabrication after fabrication operations according to one or more embodiments of the invention;

FIGS. 16A, 16B, 16C, 16D, 16E, and 16F respectively depict a top view and cross-sectional views of a portion of an IC under-fabrication after fabrication operations according to one or more embodiments of the invention;

FIGS. 17A, 17B, 17C, 17D, 17E, and 17F respectively depict a top view and cross-sectional views of a portion of an IC under-fabrication after fabrication operations according to one or more embodiments of the invention;

FIGS. 18A, 18B, 18C, and 18D respectively depict cross-sectional views of a portion of an IC under-fabrication after fabrication operations according to one or more embodiments of the invention;

FIGS. 19A, 19B, 19C, and 19D respectively depict cross-sectional views of a portion of an IC under-fabrication after fabrication operations according to one or more embodiments of the invention;

FIGS. 20A, 20B, 20C, and 20D respectively depict cross-sectional views of a portion of an IC under-fabrication after fabrication operations according to one or more embodiments of the invention;

FIGS. 21A, 21B, 21C, and 21D respectively depict cross-sectional views of a portion of an IC under-fabrication after fabrication operations according to one or more embodiments of the invention;

FIGS. 22A, 22B, 22C, and 22D respectively depict cross-sectional views of a portion of an IC under-fabrication after fabrication operations according to one or more embodiments of the invention;

FIGS. 23A, 23B, 23C, and 23D respectively depict cross-sectional views of a portion of an IC under-fabrication after fabrication operations according to one or more embodiments of the invention;

FIGS. 24A, 24B, 24C, and 24D respectively depict cross-sectional views of a portion of an IC under-fabrication after fabrication operations according to one or more embodiments of the invention; and

FIGS. 25A, 25B, 25C, and 25D respectively depict cross-sectional views of a portion of an IC under-fabrication after fabrication operations according to one or more embodiments of the invention.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A known GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

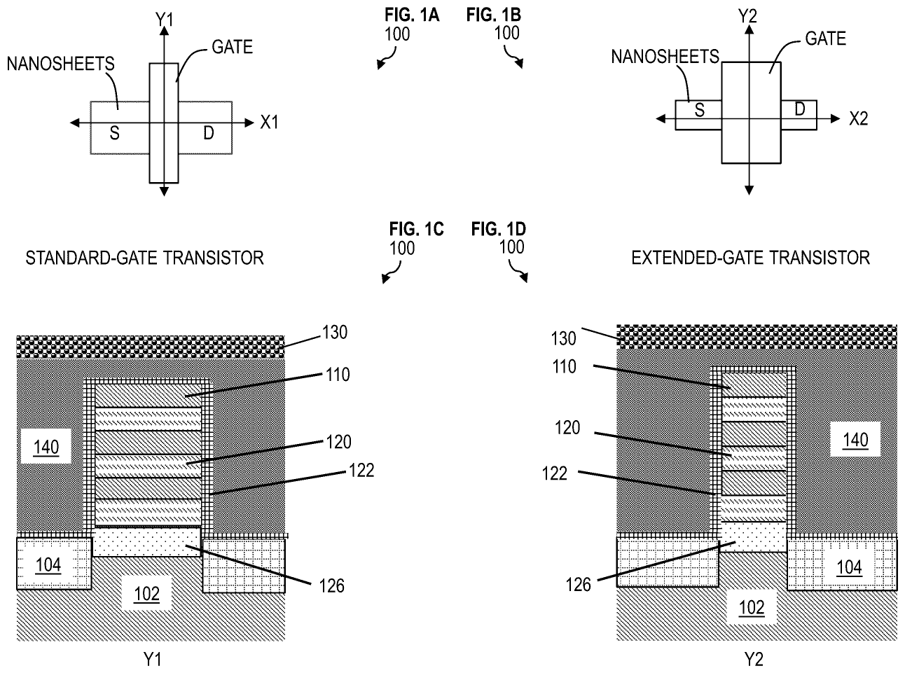

Turning now to a more detailed description of aspects of the present invention, FIGS. 1A and 1B depict top views of a simplified illustration of portion of an integrated circuit (IC) 100, and FIGS. 1C, 1D, 1E, and 1F depict cross-sectional view taken along Y1, Y2, X1, and X2 respectively of the IC 100. For ease of understanding, some layers may be omitted from the various top views so as not to obscure the figure and to view layers underneath. As such, the top view is intended to provide a simplified illustration and a general orientation, but the top view is not intended to be a complete representation of the device. Standard semiconductor fabrication techniques can be utilized to fabricate the IC 100 as understood by one of ordinary skill in the art. Any suitable lithography processes including deposition techniques and etching techniques can be utilized herein.

The transistor depicted in the X1 and Y1 views represents a standard-gate (SG) field effect transistor, such as a logic transistor, on the IC 100. The transistor depicted in the X2 and Y2 views represents an extended-gate (EG) field effect transistor on the IC 100, where the gate structure of the extended-gate is wider in the x-axis than the gate structure of the standard-gate field effect transistor. Both gate structures can made of the same materials.

FIGS. 1A, 1B, 1C, 1D, 1E, and 1F depict the IC 100 having a wafer where several fabrication processes have been performed. The figures illustrate the IC 100 after nanosheet stack growth and nanosheet patterning. A nanosheet stack is formed on a substrate 102 (or wafer). The substrate 102 may be formed of (pure) silicon. Other suitable semiconductor materials can be utilized for the substrate 102. As seen in FIGS. 1C, 1D, 1E, and 1F, a nanosheet stack of semiconductor layers 110 is formed with sacrificial layers 120 in between. The semiconductor layers 110 may include substantially pure silicon. The semiconductor layers 110 will become the channel regions for the nanosheet FET device. The semiconductor layers 110 are nanosheets, and the nanosheets can have a thickness of, for example, 5 nanometers. The thickness of a nanosheet can range from about 2-10 nm, and other ranges are possible. The sacrificial layers 120 are formed of silicon germanium (SiGe), where germanium has an atomic percent (%) of about 25% and silicon is the remainder. In one or more embodiments, the atomic percent of germanium can range from about 15-30% while silicon is the remainder in the sacrificial layer 120.

A bottom isolation layer 126 is formed above the substrate 102 and below the semiconductor layers 110. Example materials of the bottom isolation layer 126 can include nitride materials, low-k materials, ultra-low-materials, etc. Inner spacers 160 are formed at the ends of the sacrificial layers 120. Example materials of the inner spacers 160 can include nitrides, low-k dielectric materials, etc. Other example materials of the inner spacers 160 may include SiBCN, SiOCN, SiN, SiOC, SiC, etc. In one or more embodiments, the bottom isolation layer 126 may be omitted.

Source/drain regions 150 are formed of epitaxial material grown on the sides of the semiconductor layers 110. The epitaxial material can be doped with n-type or p-type dopants according to whether an n-type or p-type transistor is being formed. A dummy oxide 122 is formed around the nanosheet stack of semiconductor layers 110, and a dummy gate 140 is formed over the dummy oxide 122. Example materials of the dummy oxide 122 can include oxides such as silicon dioxide, aluminum oxide, etc. Example materials of the dummy gate 140 can include amorphous silicon, polycrystalline silicon, etc.

Gate spacers 142 are formed on the sides of the dummy gate 140, and a hard mask layer 130 is formed on top of the dummy gate 140. Example materials of the hard mask layer 130 can include nitride materials such as silicon nitride (SiN), oxynitrides, etc. Example materials of the gate spacers 142 can include nitride materials, such as SiN, SiBCN, SiOCN, SiOC, etc.

Intralayer dielectric (ILD) material 104 is formed on the substrate 102 as a fill material. The ILD material 104 can include low-k materials and ultra-low-k materials.

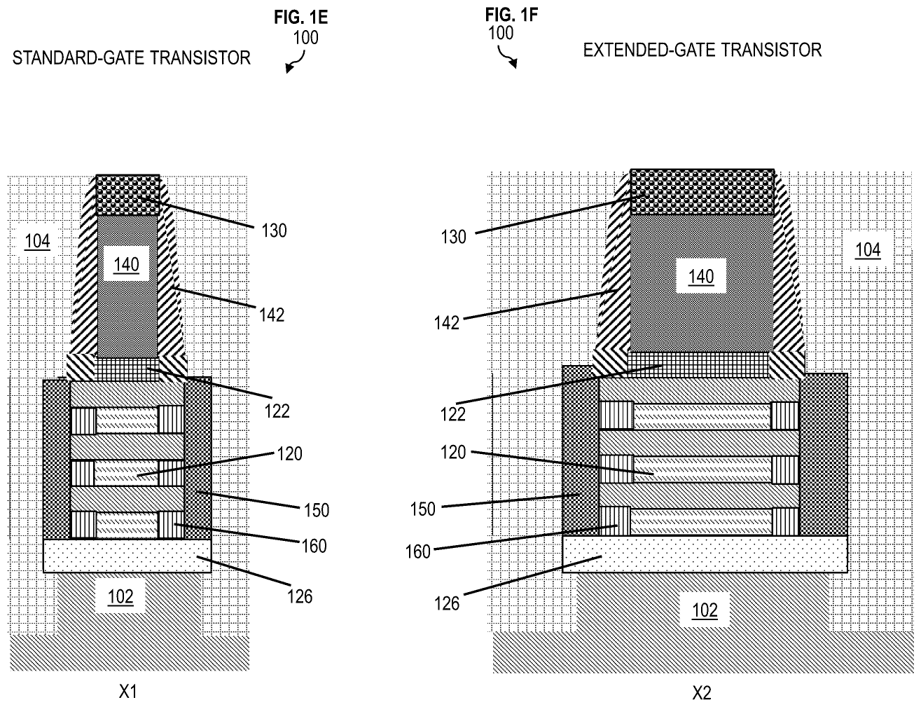

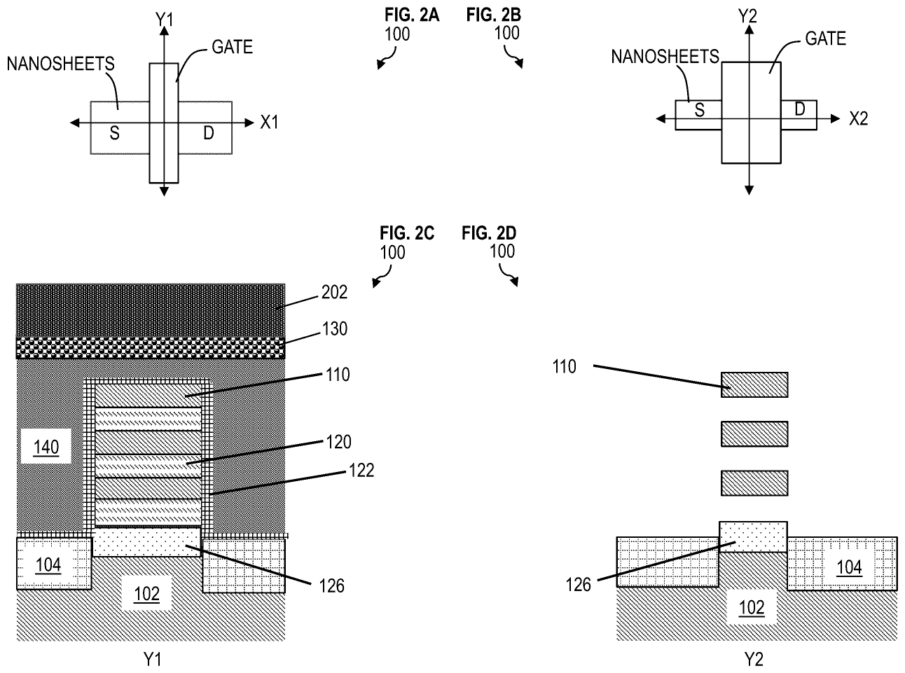

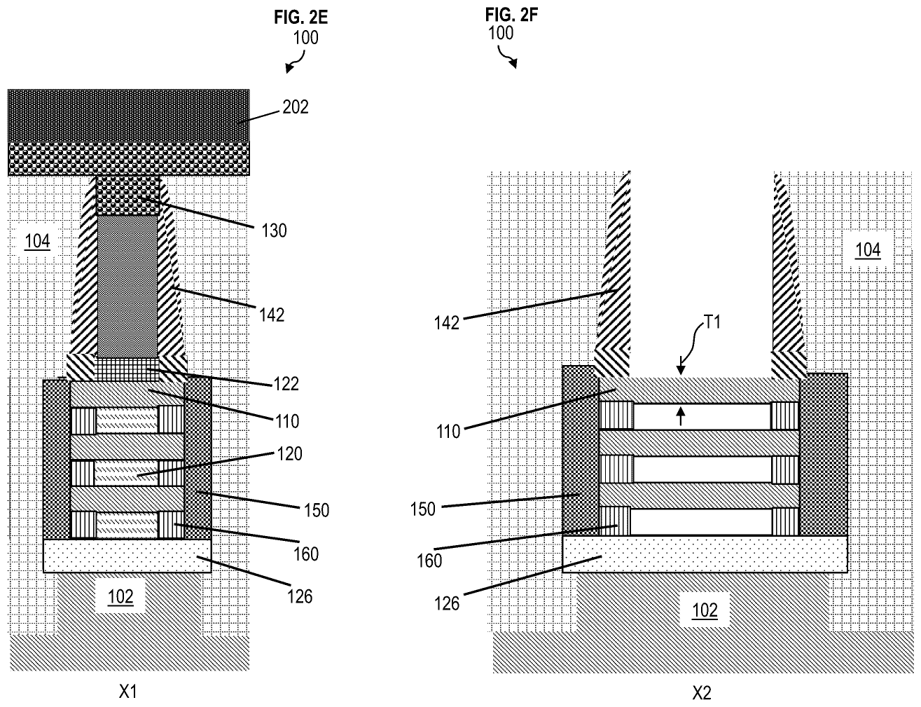

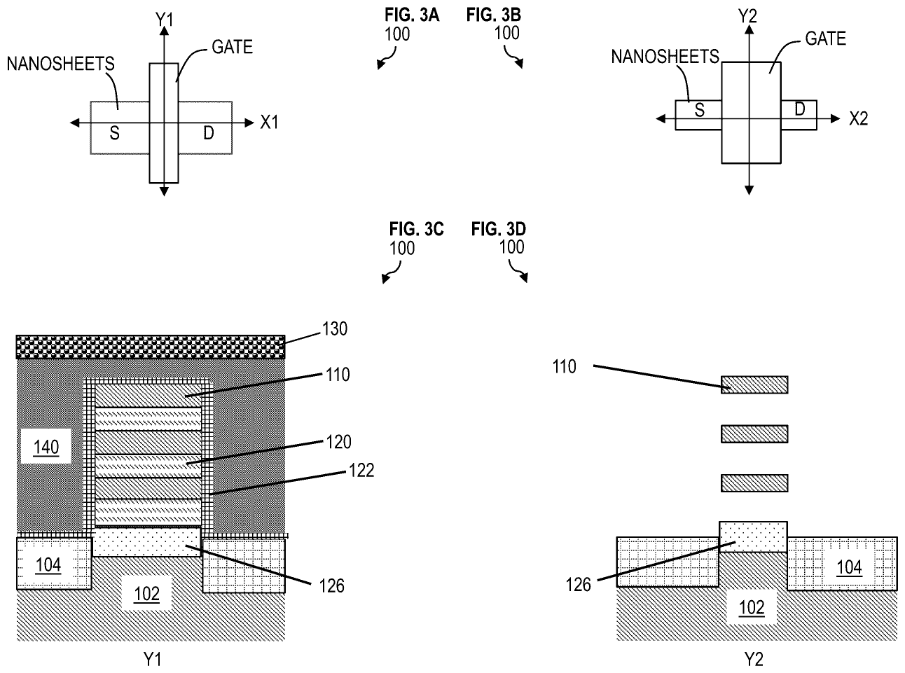

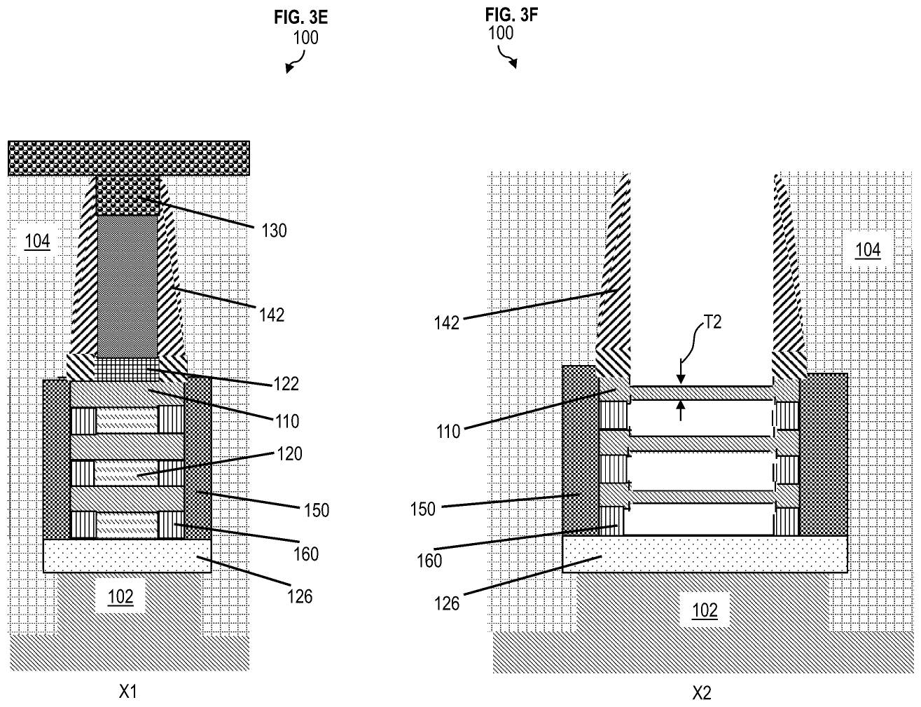

FIGS. 2A, 2B, 2C, 2D, 2E, and 2F depict the IC 100 after nanosheet release (or poly pull). Lithography is performed to form a block mask 202 over the standard-gate transistor depicted in FIGS. 2C and 2E, as protection for subsequent fabrication processes. For the (unprotected) extended-gate transistor, the hard mask layer 130 is removed, and the semiconductor layers 110 are released. As such, the dummy gate 140, the dummy oxide 122, and the sacrificial layers 120 are etched as depicted in FIGS. 2D and 2F. The channel regions of the semiconductor layers 110 have a thickness T1 in FIGS. 2D and 2F, where the thickness T1 is greater than the thickness T2 depicted in FIGS. 3D and 3F.

FIGS. 3A, 3B, 3C, 3D, 3E, and 3F depict the IC 100 after trimming the channel regions. While the standard-gate transistor is protected, the channel regions of semiconductor layers 110 in the extended-gate transistor are trimmed from thickness T1 to thickness T2, resulting in a trimmed middle portion. Etching is performed to trim the thickness of the semiconductor layers 110 of the extended-gate transistor. The block mask 202 is removed.

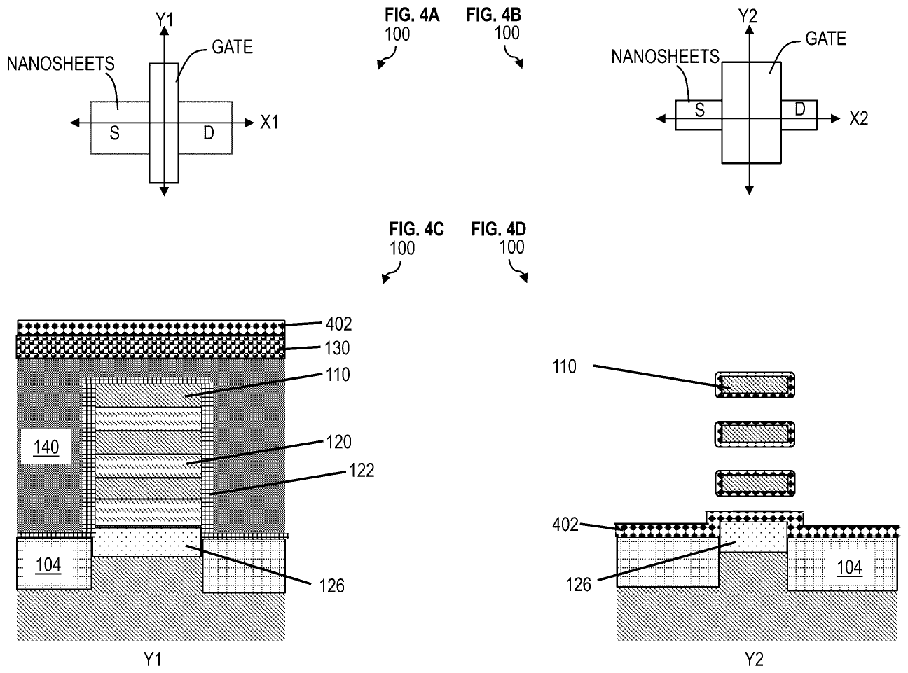

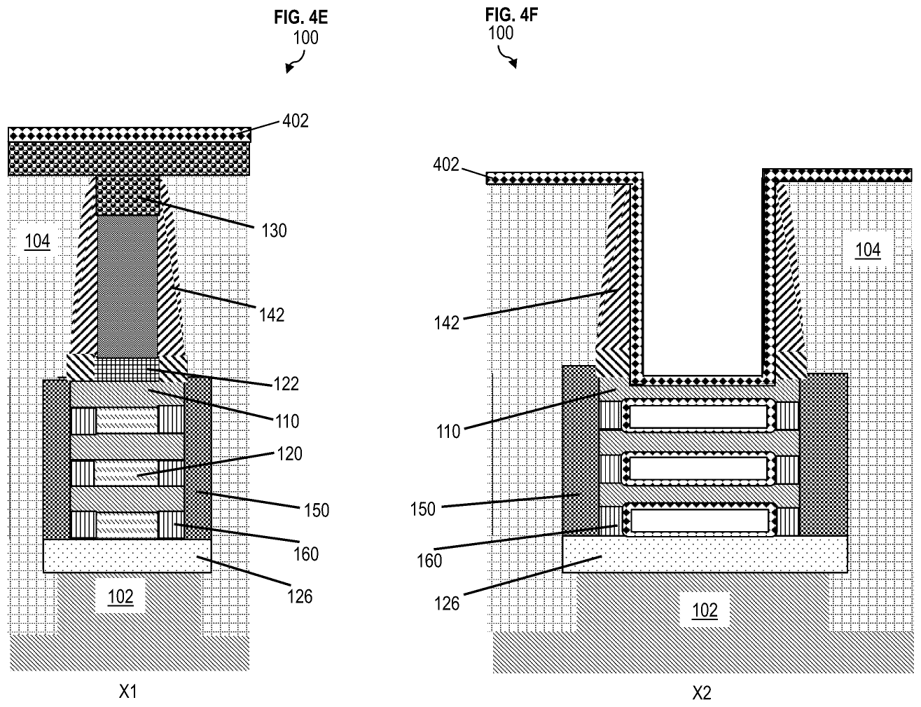

FIGS. 4A, 4B, 4C, 4D, 4E, and 4F depict the IC 100 after oxide deposition. An oxide layer 402 is deposited on the standard-gate transistor and the extended-gate transistor. Example materials of the oxide layer 402 can include silicon dioxide, aluminum oxide, etc.

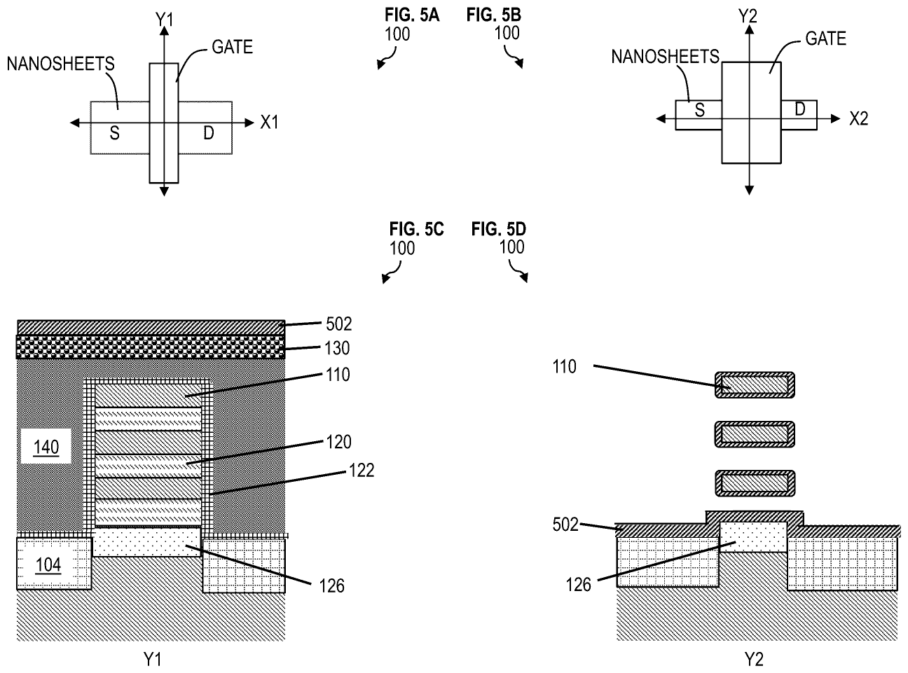

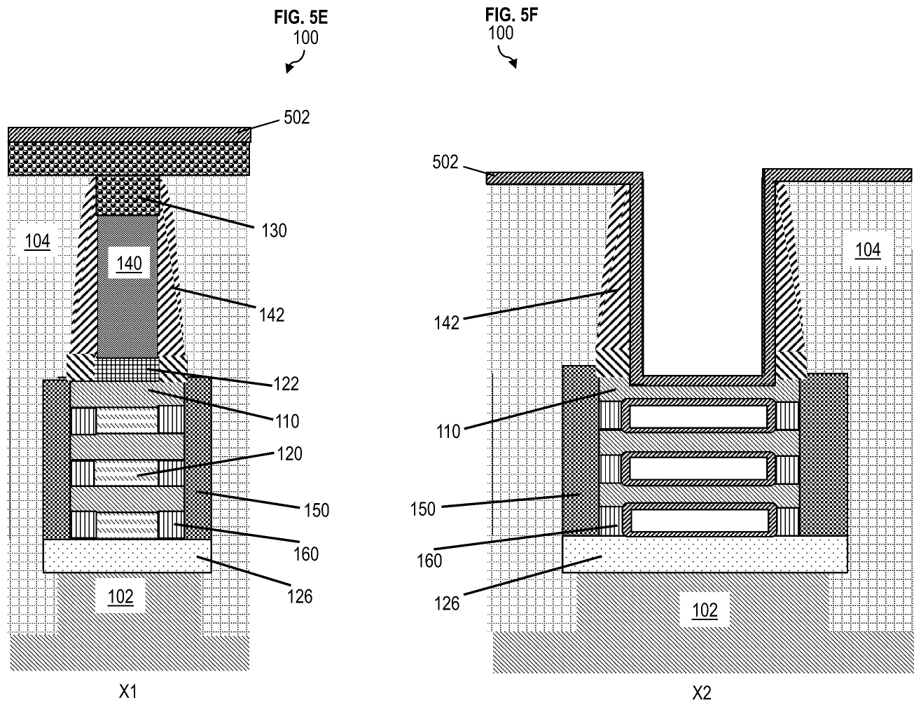

FIGS. 5A, 5B, 5C, 5D, 5E, and 5F depict the IC 100 after a nitridation treatment. A nitridation treatment is performed to convert the oxide layer 402 to a nitride layer 502 (or nitride oxide layer) by infusing the oxide layer 402 with nitrogen atoms and then annealing, thereby resulting in the nitride layer 502.

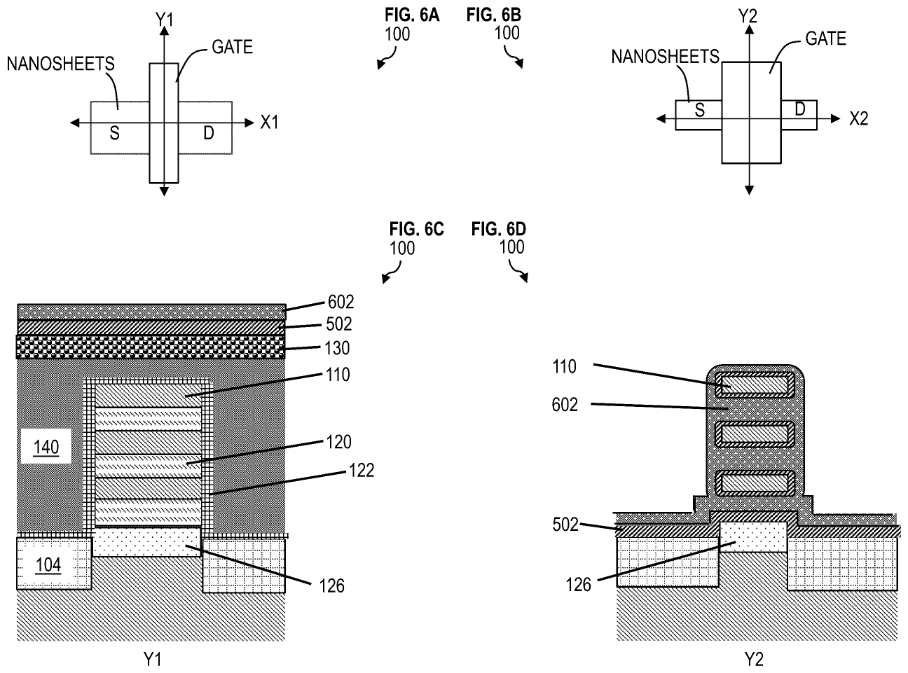

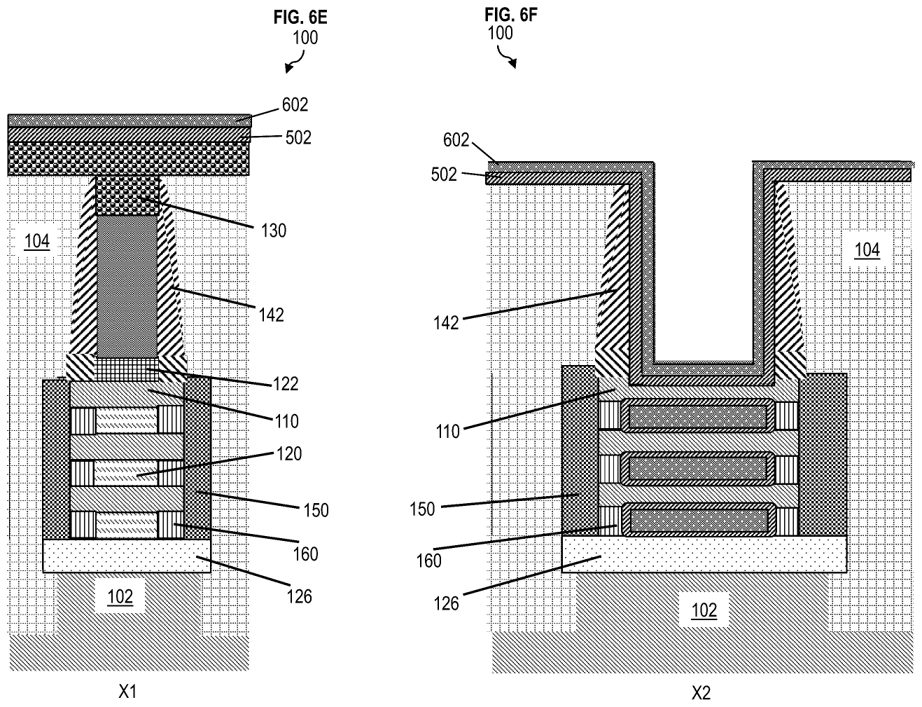

FIGS. 6A, 6B, 6C, 6D, 6E, and 6F depict the IC 100 after sacrificial layer deposition. A sacrificial layer 602 is deposited on the nitride layer 502. Example materials of the sacrificial layer 602 can include oxide materials, such as silicon dioxide, aluminum oxide, etc. The sacrificial layer 602 may be about 2 nanometers (nm) according to one or more embodiments.

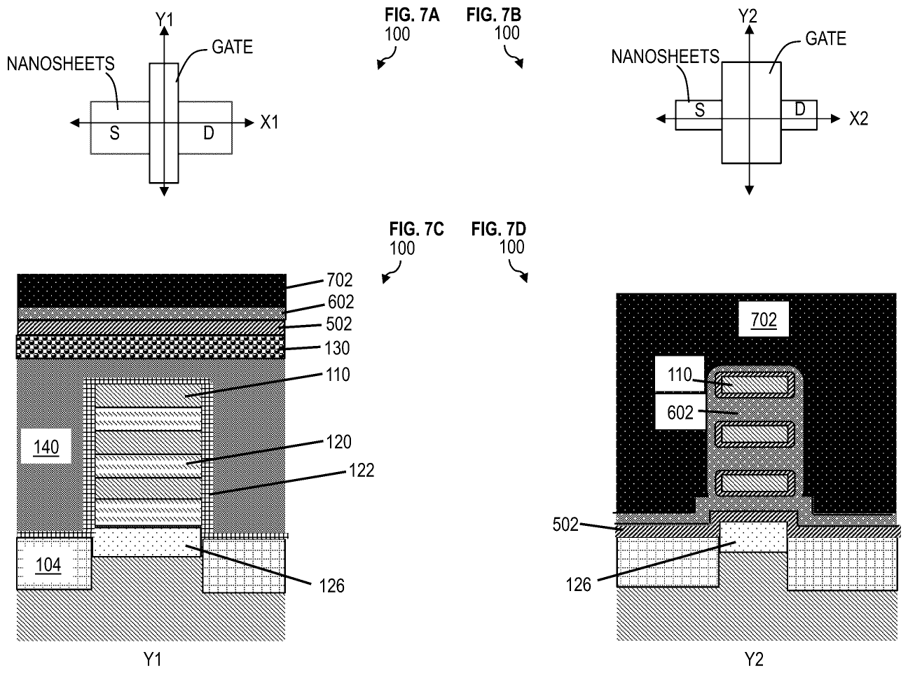

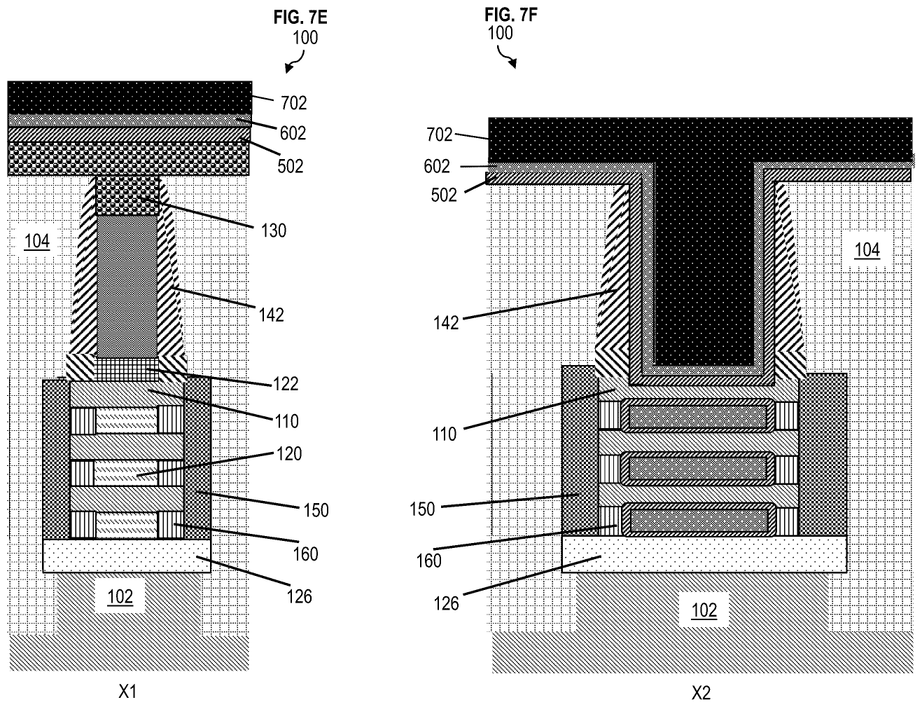

FIGS. 7A, 7B, 7C, 7D, 7E, and 7F depict the IC 100 after deposition of a block mask 702. The block mask 702 is deposited.

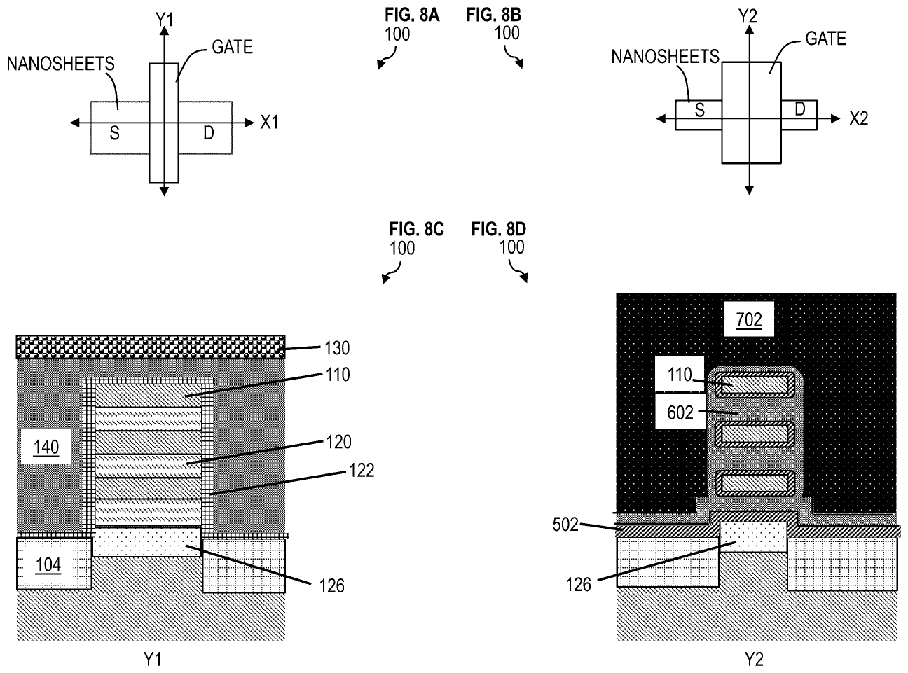

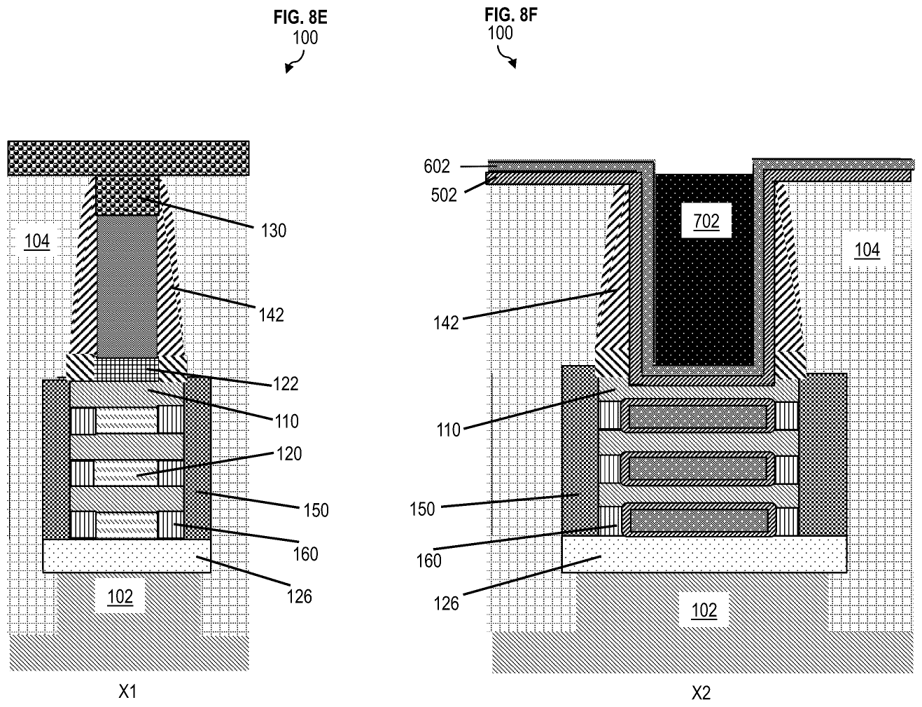

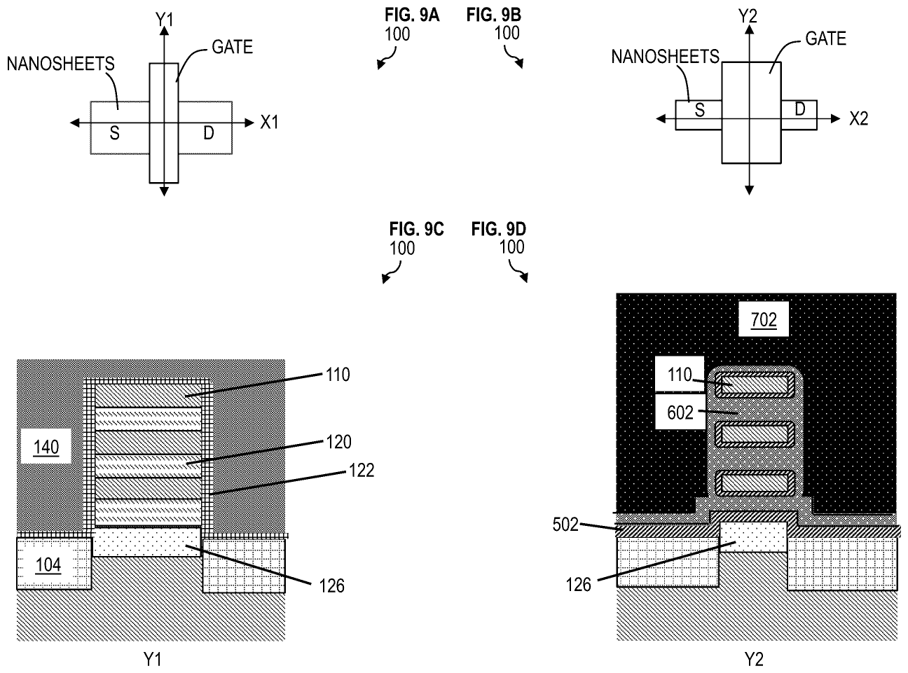

FIGS. 8A, 8B, 8C, 8D, 8E, and 8F depict the IC 100 after patterning the block mask and further etching. Patterning and etching are performed, resulting in the block mask 702 being recessed in the extended-gate transistor and resulting in the hard mask layer 130 being exposed in the standard-gate transistor.

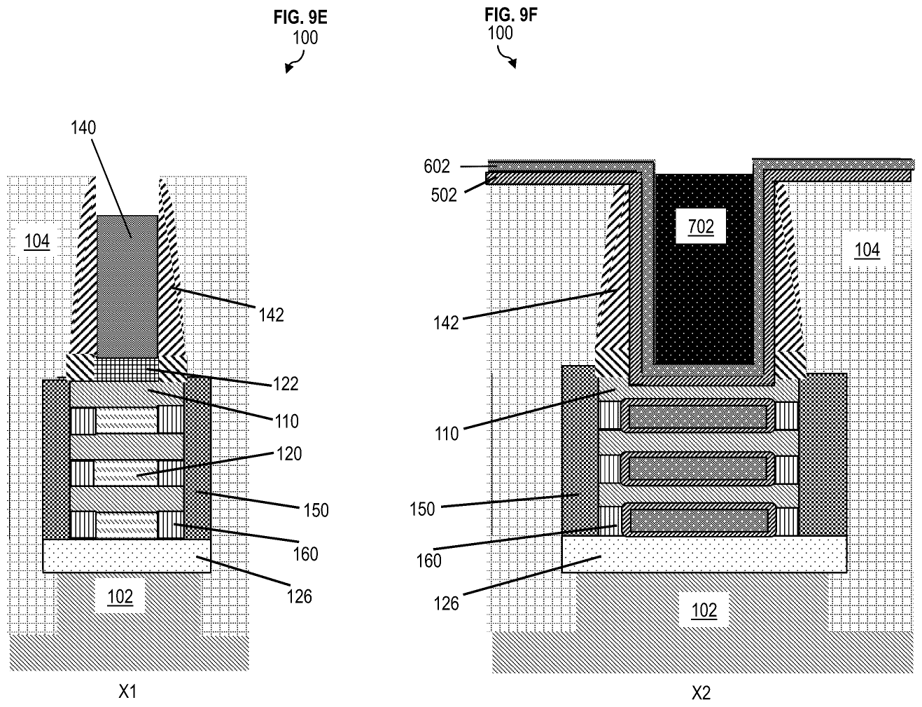

FIGS. 9A, 9B, 9C, 9D, 9E, and 9F depict the IC 100 after removal of the block mask 702. Etching is performed to remove portion of the block mask 702, such that the dummy gate 140 is exposed.

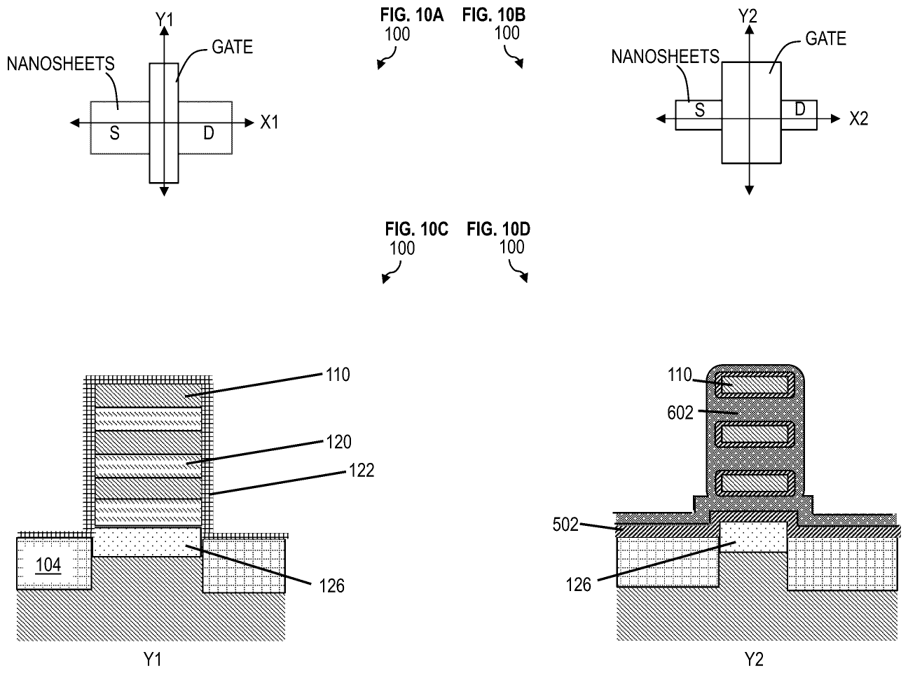

FIGS. 10A, 10B, 10C, 10D, 10E, and 10F depict the IC 100 after dummy gate pull. Etching is performed to remove the dummy gate 140 and the dummy gate 140. The block mask 702 is removed, for example, by ashing.

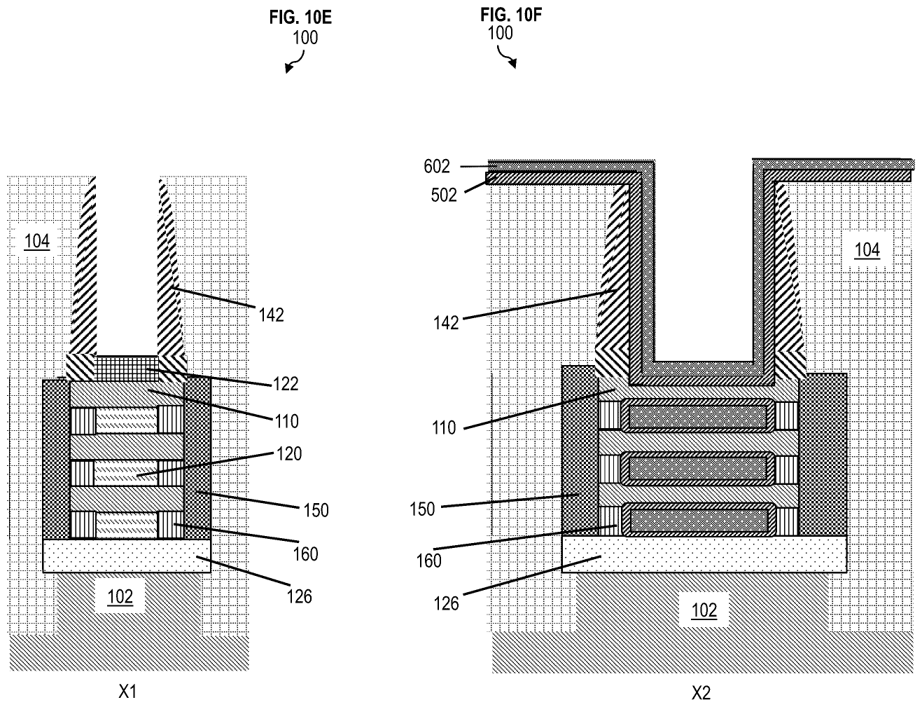

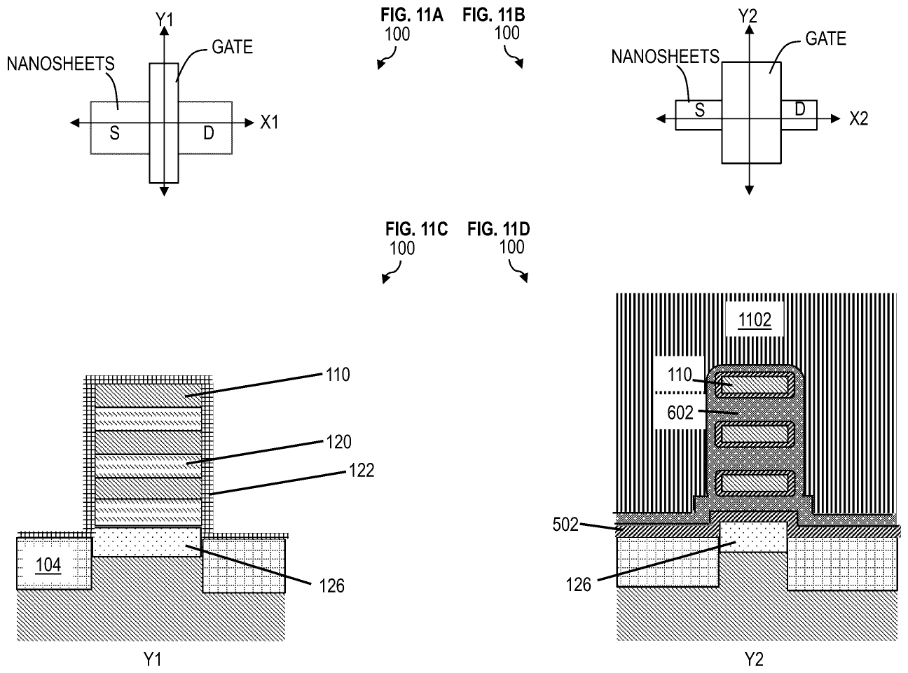

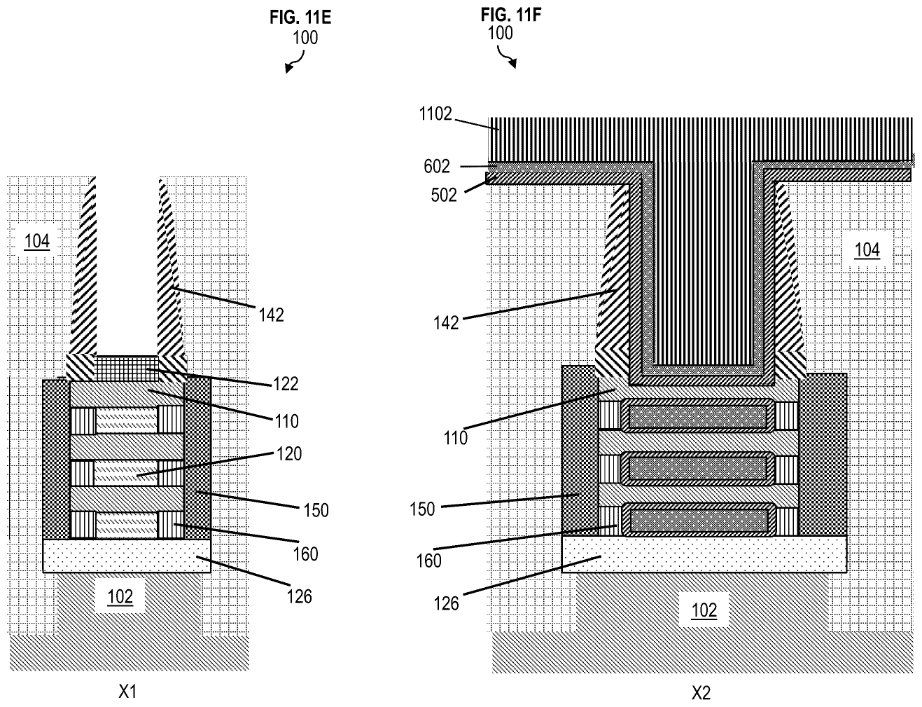

FIGS. 11A, 11B, 11C, 11D, 11E, and 11F depict the IC 100 after patterning the block mask and further etching. A block mask 1102 is formed. Patterning and etching are performed, resulting in the block mask 1102 being recessed in the extended-gate transistor, and the hard mask layer 130 being exposed in the standard-gate transistor.

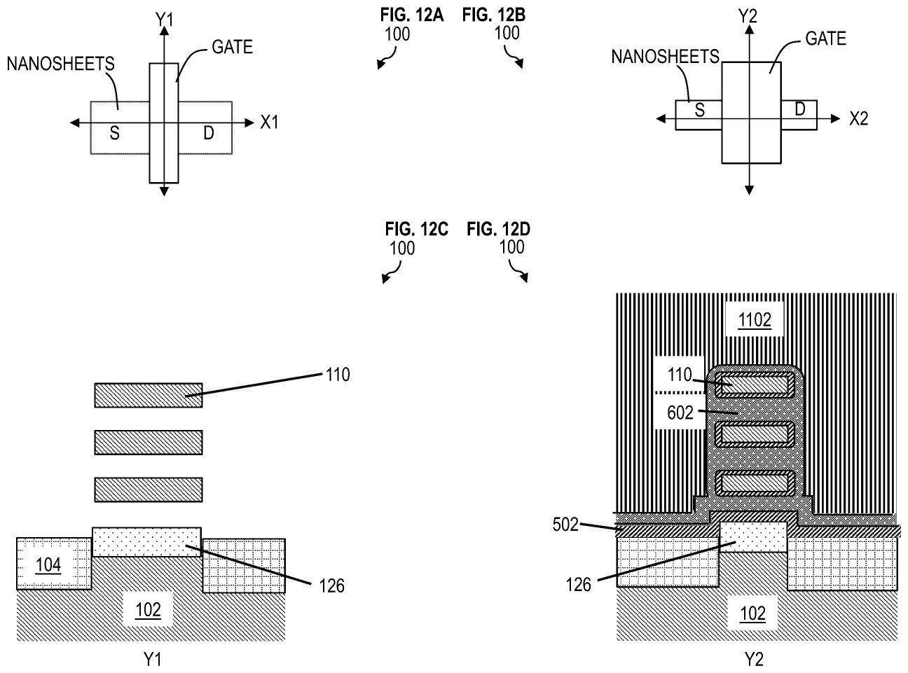

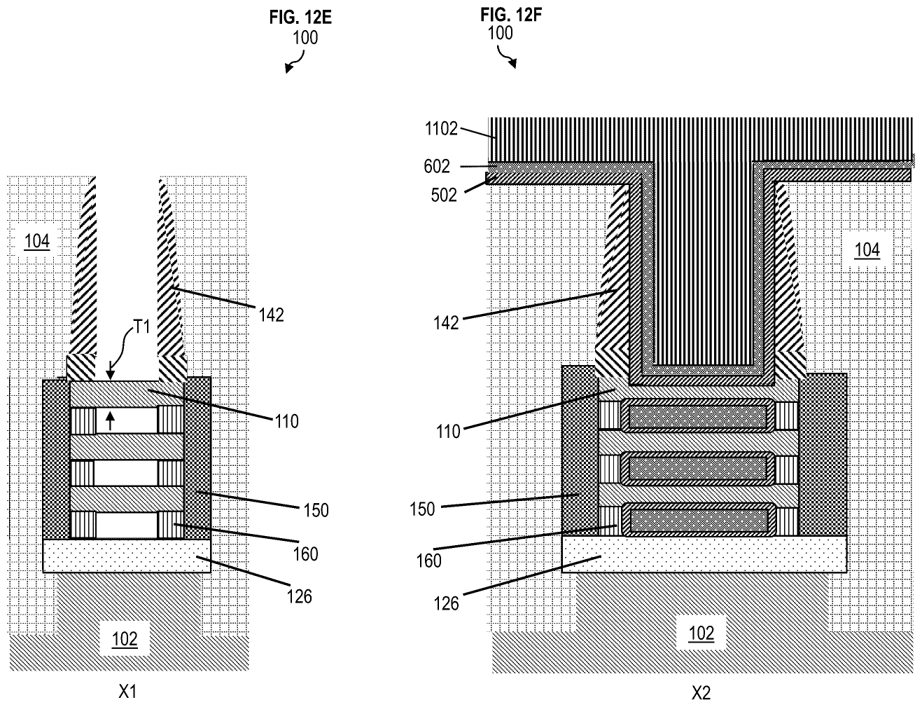

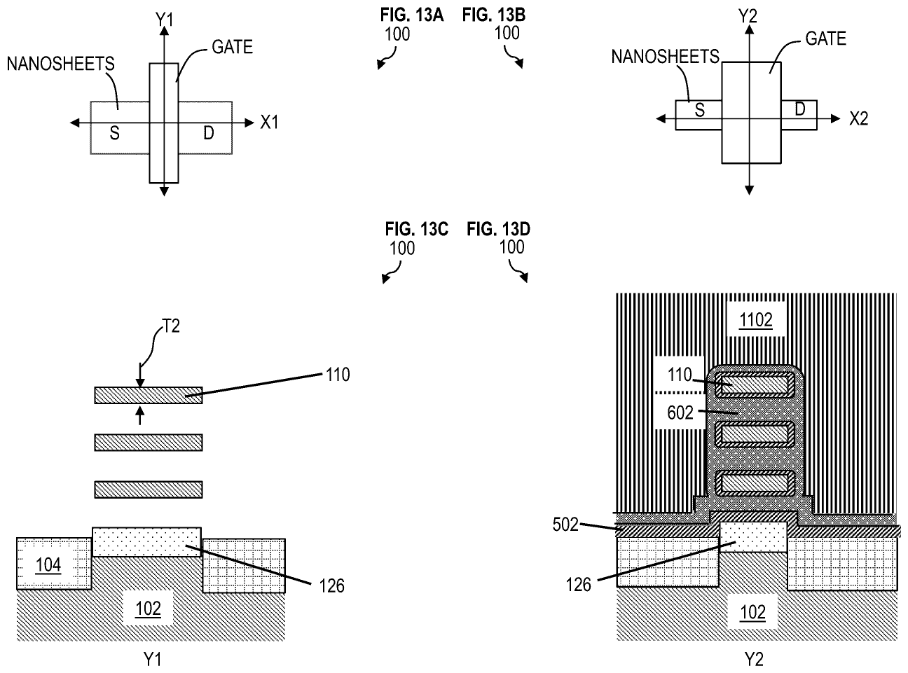

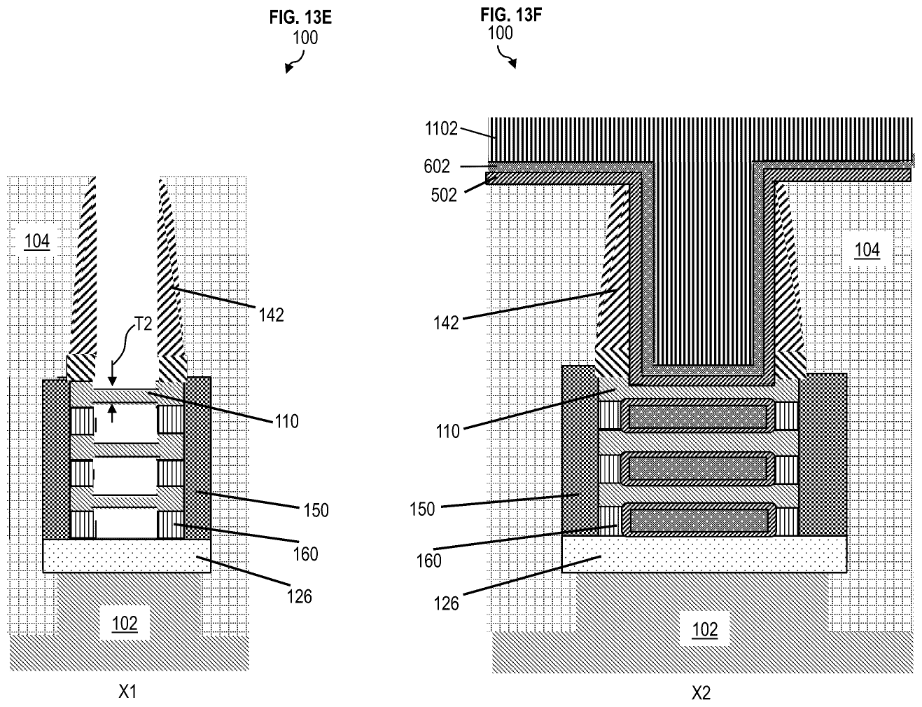

FIGS. 12A, 12B, 12C, 12D, 12E, and 12F depict the IC 100 after nanosheet release. For the unprotected standard-gate transistor, the semiconductor layers 110 are released. As such, the dummy oxide 122 and the sacrificial layers 120 are etched as depicted in FIGS. 12C and 12E. In the unprotected standard-gate transistor, the channel regions of the semiconductor layers 110 have a thickness T1 in FIGS. 12C and 12E which is greater than the thickness T2 depicted in FIGS. 13C and 13E.

FIGS. 13A, 13B, 13C, 13D, 13E, and 13F depict the IC 100 after trimming the channel regions of the semiconductor layers 110. The channel regions of the standard-gate transistor are trimmed to the thickness T2, while the extended-gate transistor is protected, resulting in a trimmed middle portion.

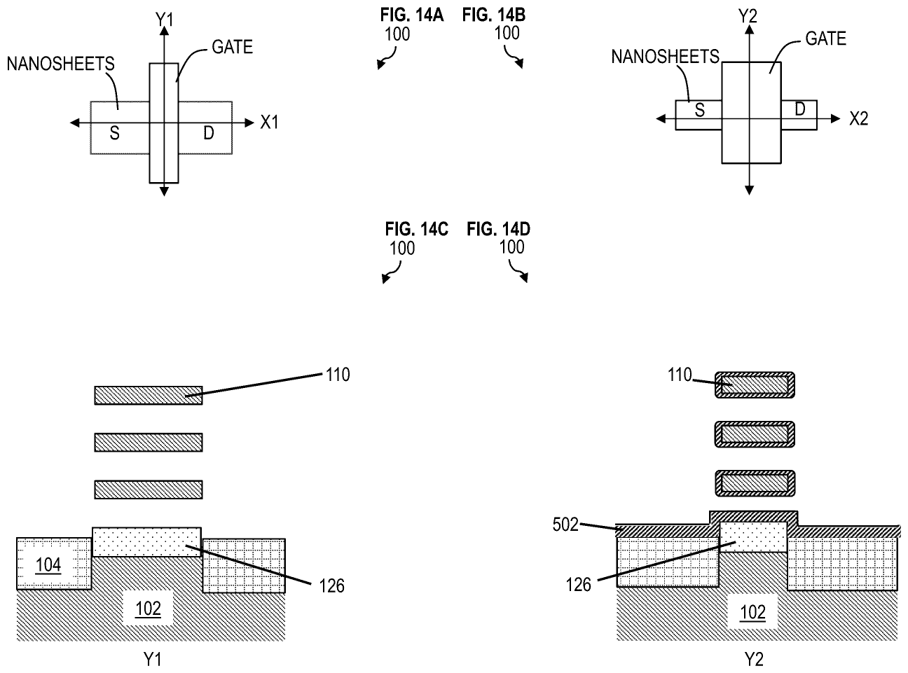

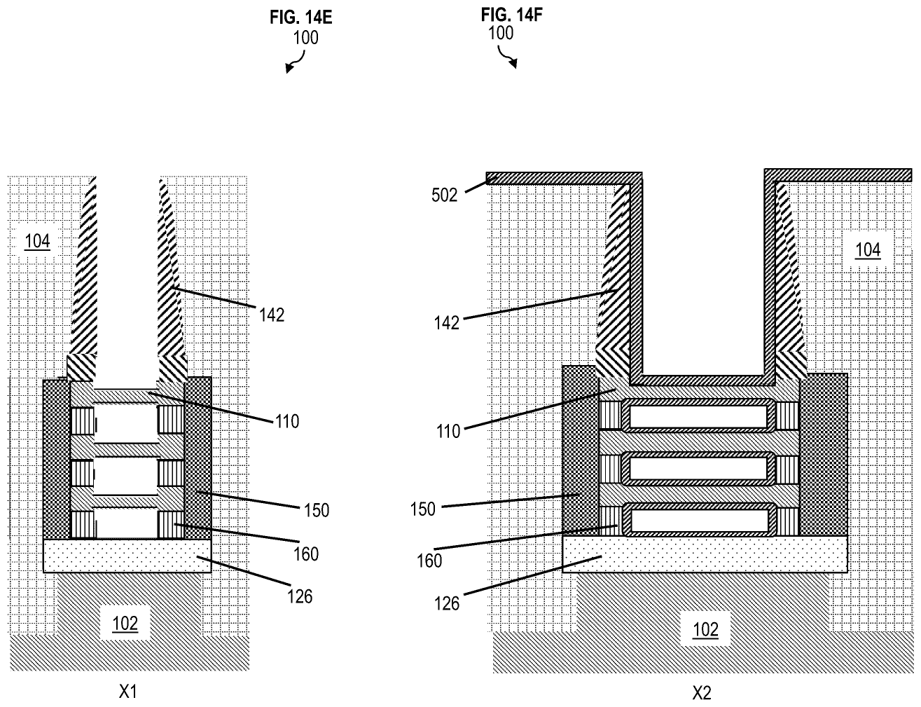

FIGS. 14A, 14B, 14C, 14D, 14E, and 14F depict the IC 100 after removal of the sacrificial layer 602. The block mask 1102 is removed, for example, by ashing to expose the sacrificial layer 602. Etching is performed to remove the (exposed) sacrificial layer 602.

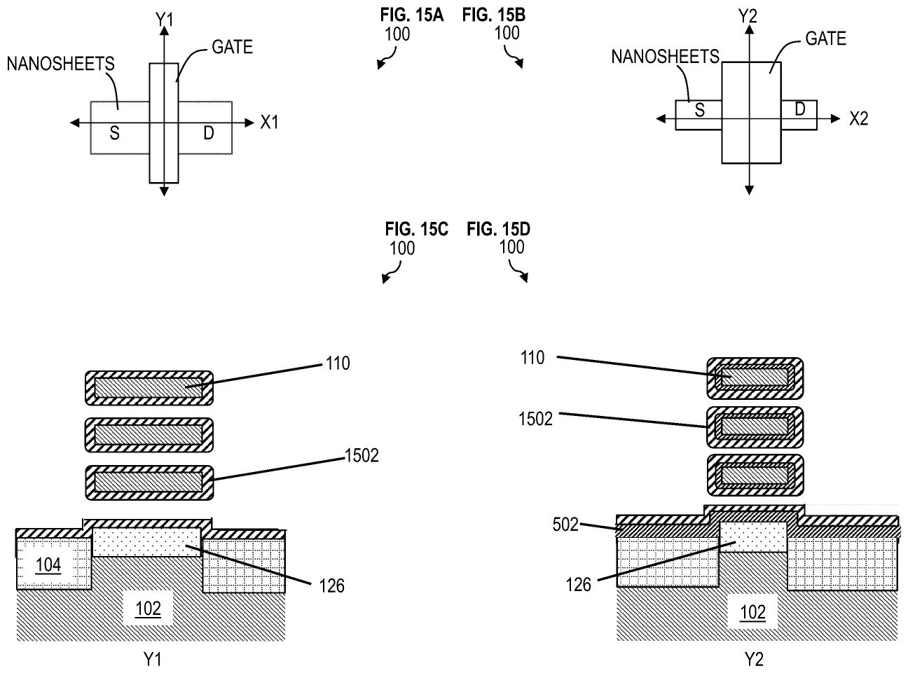

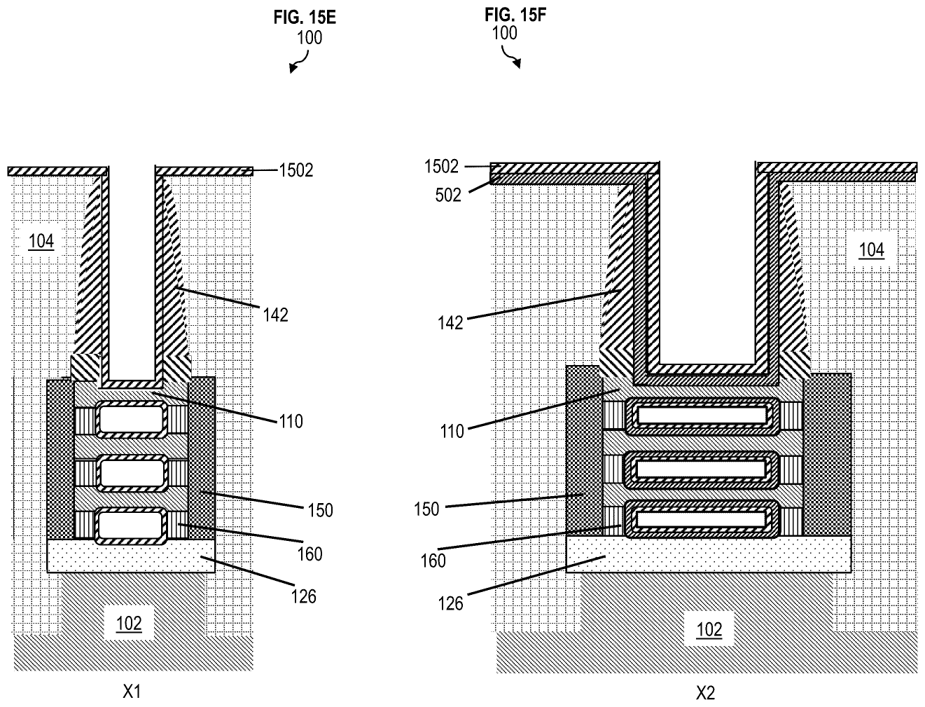

FIGS. 15A, 15B, 15C, 15D, 15E, and 15F depict the IC 100 after high-k material deposition. Deposition is performed to form high-k dielectric layer 1502. Example materials of the high-k dielectric layer 1502 can include hafnium dioxide (HfO₂), etc., and other high-k dielectric materials. In one or more embodiments, there may be a thin oxide layer intervening between the high-k dielectric layer 1502 and the silicon of the channel region in the standard-gate transistor. The thickness of the thin intervening oxide layer can be about 6 Å. In one or more embodiments, the thickness of thin intervening oxide layer can range from 6-11 Å.

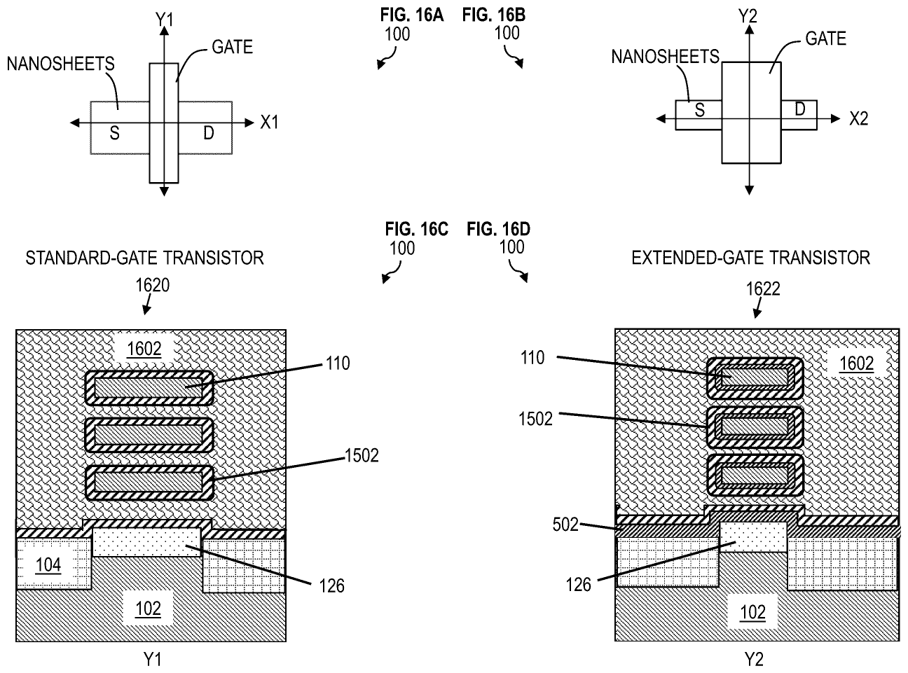

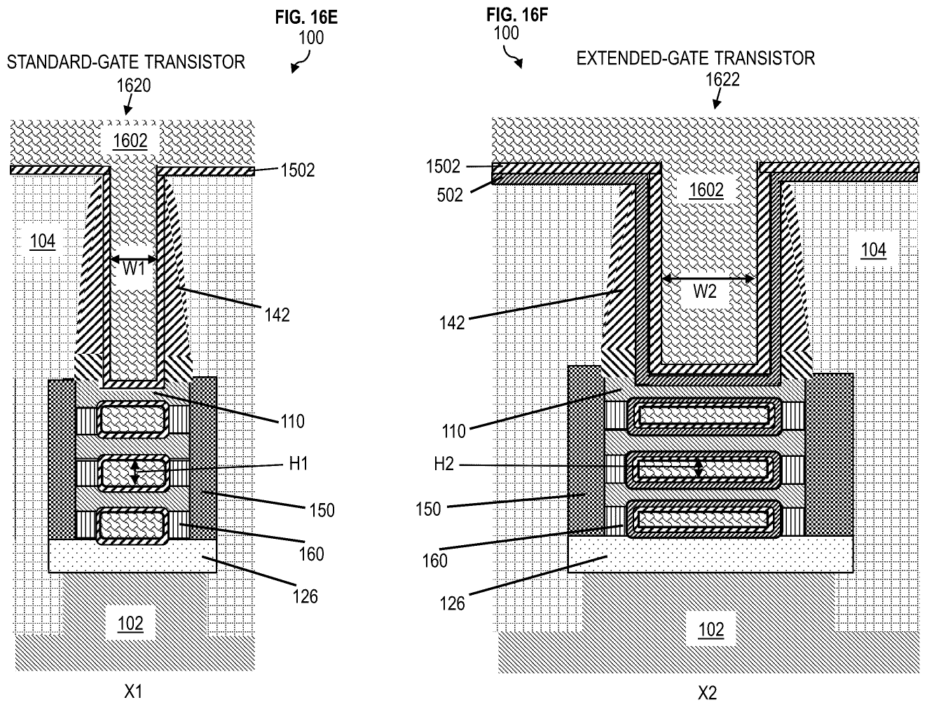

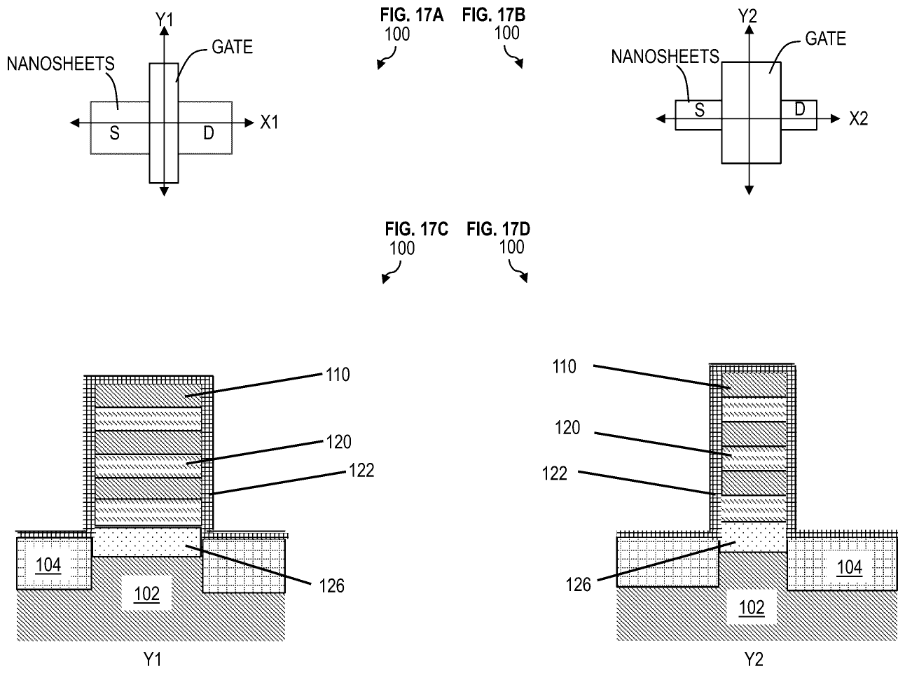

FIGS. 16A, 16B, 16C, 16D, 16E, and 16F depict the IC 100 after a replacement metal gate process. A gate structure 1602 is formed around the channel regions of semiconductor layers 110. This results in a standard-gate transistor 1620 and an extended-gate transistor 1622 on the (same) IC 100. The gate structure 1602 can include high-k material and work function material formed on the high-k material. In one or more embodiments, the high-k dielectric layer 1502 may serve as the high-k material for the gate structure 1602, such that the work function material is formed on the high-k dielectric layer 1502 without additional high-k material. In one or more embodiments, additional high-k material can be formed in the gate structure 1602.

The standard-gate transistor 1620 has a first thickness H1 of the gate structure 1602 between its channel regions of semiconductor layers 110. The extended-gate transistor 1622 has a second thickness H2 of the gate structure 1602 between its channel regions of semiconductor layers 110. The first thickness H1 is greater than a second thickness H2, because of the presence of the nitride layer 502 in the extended-gate transistor 1622.

The gate structure 1602 in the standard-gate transistor 1620 includes a first width W1 in a first dimension, and the standard-gate transistor 1620 in the extended-gate transistor 1622 includes a second width W2 in the first dimension. The second width W2 is greater than the first width W1.

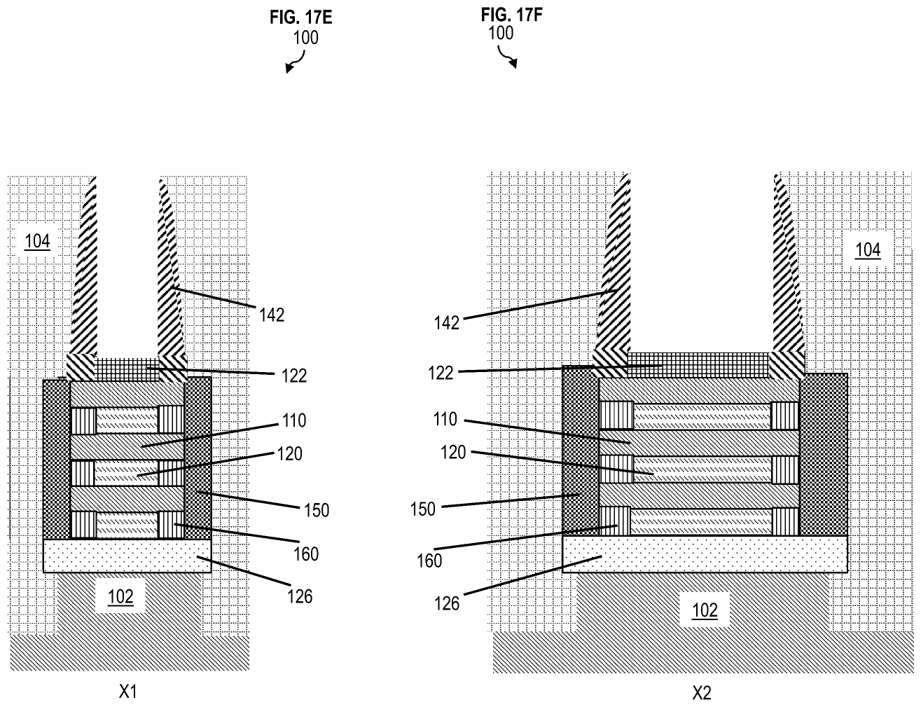

Another fabrication process flow is provided to form the standard-gate transistor 1620 and extended-gate transistor 1622 according to one or more embodiments. Just as discussed above, the fabrication process flow returns again to FIGS. 1A, 1B, 1C, 1D, 1E, and 1F. Continuing from FIGS. 1A, 1B, 1C, 1D, 1E, and 1F, FIGS. 17A, 17B, 17C, 17D, 17E, and 17F depict the IC 100 after etching the hard mask layer 130 and the dummy gate 140. Lithography can be performed to remove the hard mask layer 130 and dummy gate 140.

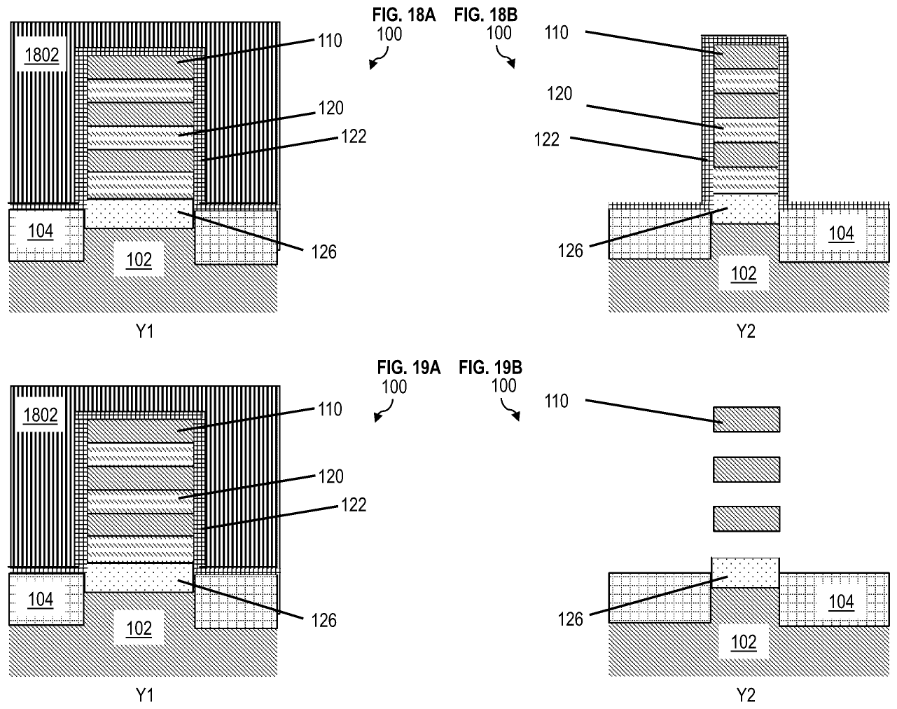

Although top views have been shown in previous figures, top views are no longer illustrated for the sake of brevity but should be understood according to one or more embodiments. FIGS. 18A, 18B, 18C, and 18D depict the IC 100 after formation of a block mask. A block mask 1802 can be deposited and patterned to protect the standard-gate transistor, while the extended-gate transistor remains unprotected.

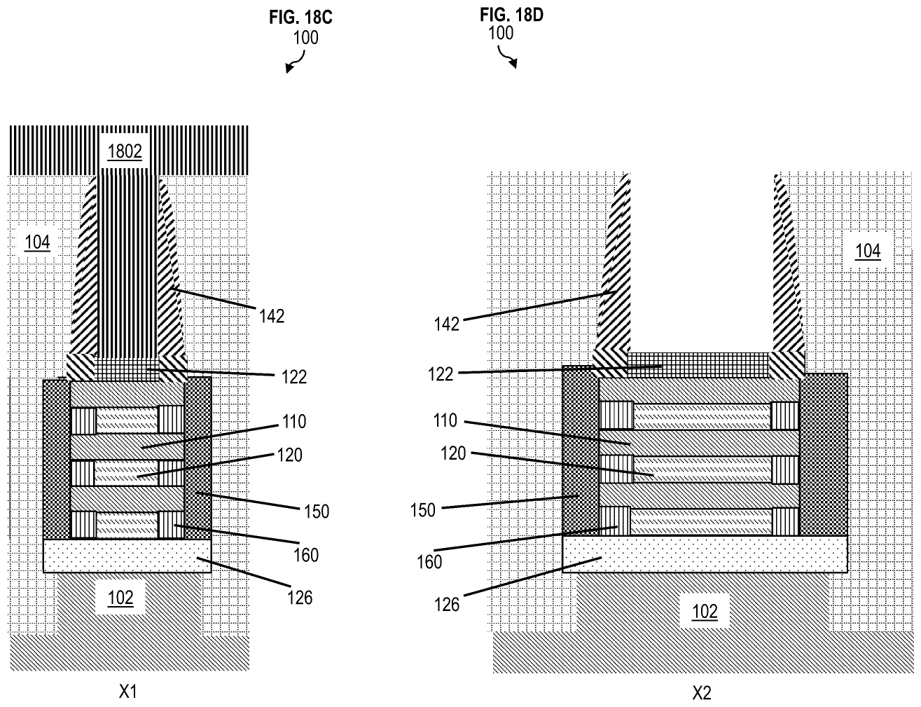

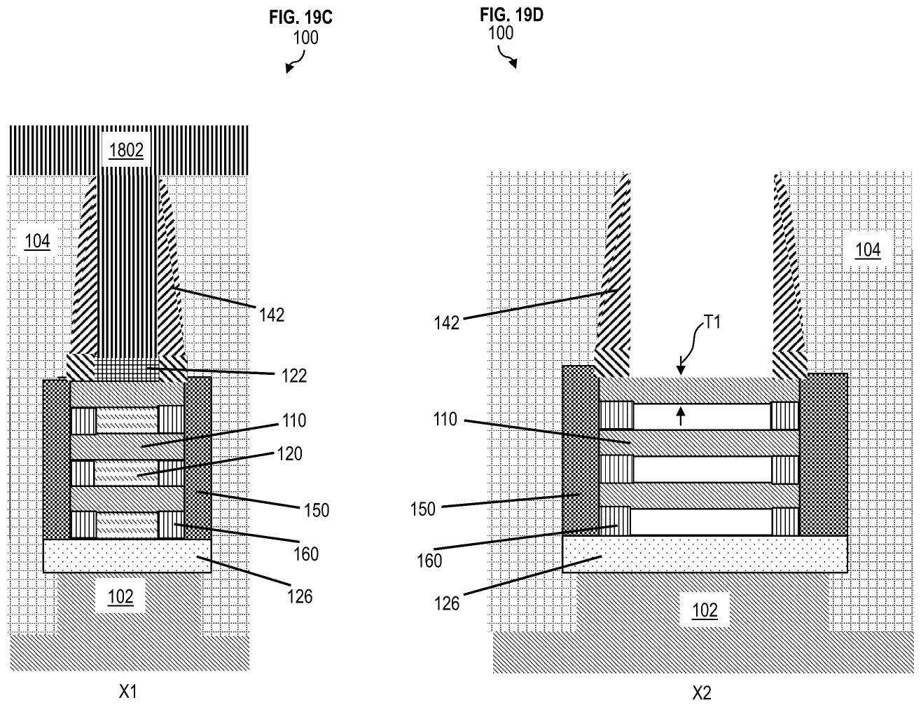

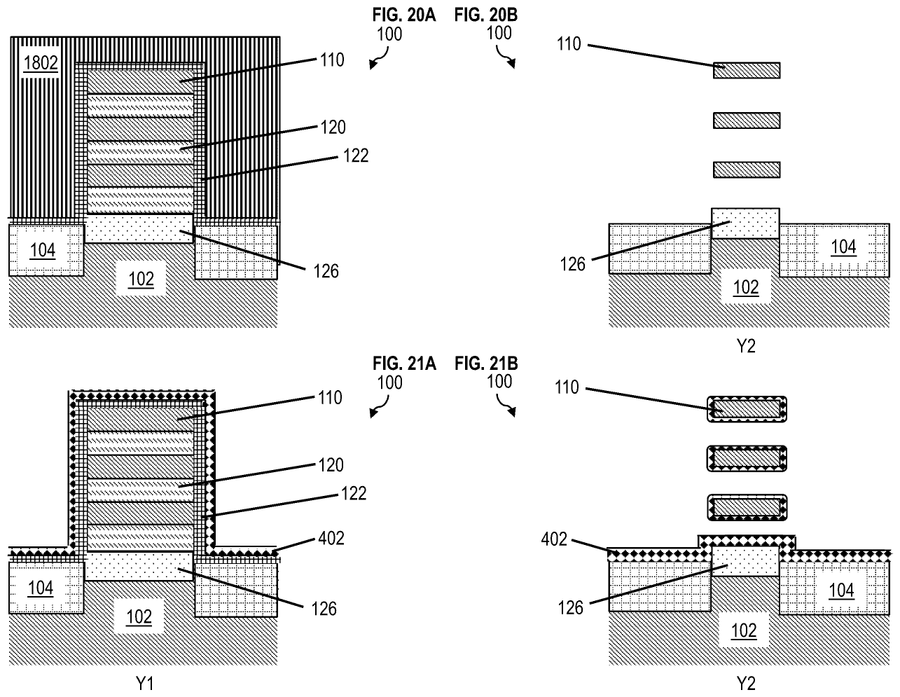

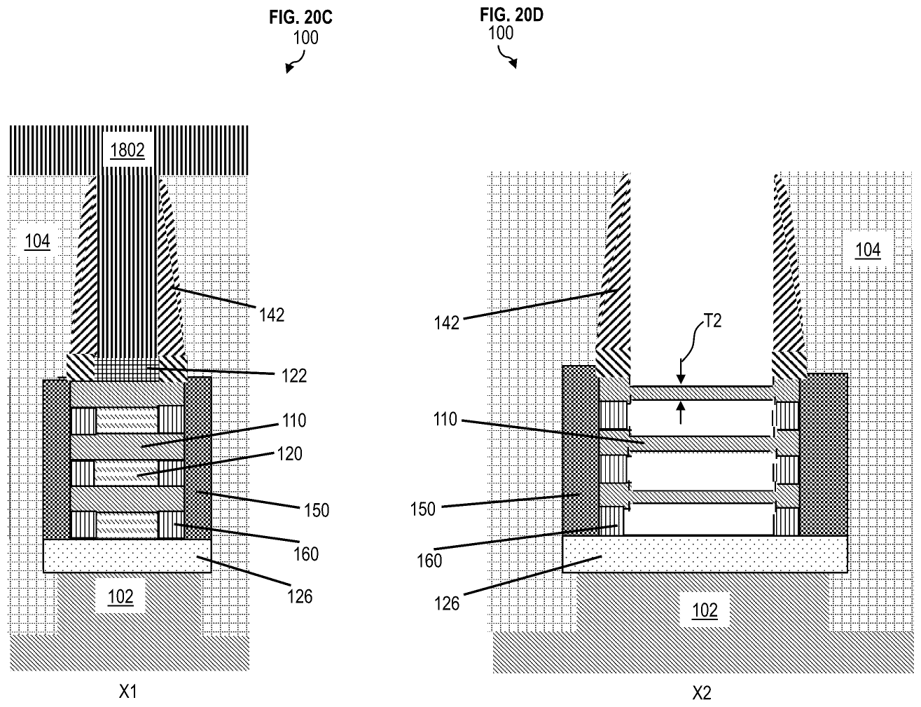

FIGS. 19A, 19B, 19C, and 19D depict the IC 100 after nanosheet release. Etching is performed to remove the dummy oxide 122 and the sacrificial layers 120 in the extended-gate transistors. The channel regions of the semiconductor layers 110 have a thickness T1 in FIGS. 19B and 19D which is greater than a thickness T2 depicted in FIGS. 20B and 20D.

FIGS. 20A, 20B, 20C, and 20D depict the IC 100 after trimming the channel regions of the semiconductor layers 110. The channel regions of the extended-gate transistor are trimmed to the thickness T2, while the standard-gate transistor is protected by the block mask 1802.

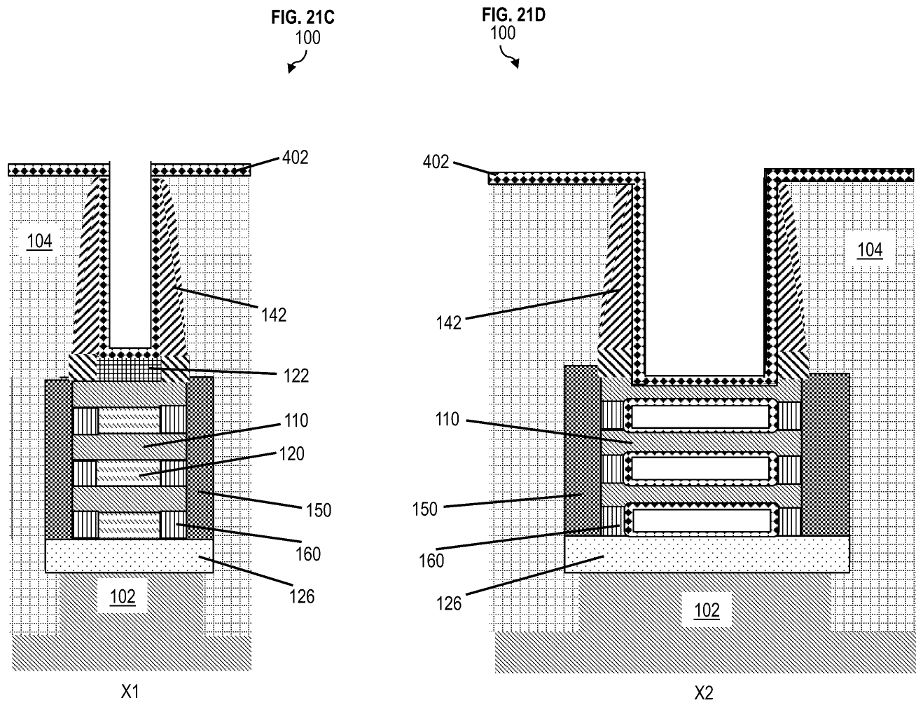

FIGS. 21A, 21B, 21C, and 21D depict the IC 100 after oxide deposition. After removal of the block mask 1802, an oxide layer 402 is deposited on the standard-gate transistor and the extended-gate transistor. Example materials of the oxide layer 402 can include silicon dioxide, aluminum oxide, etc.

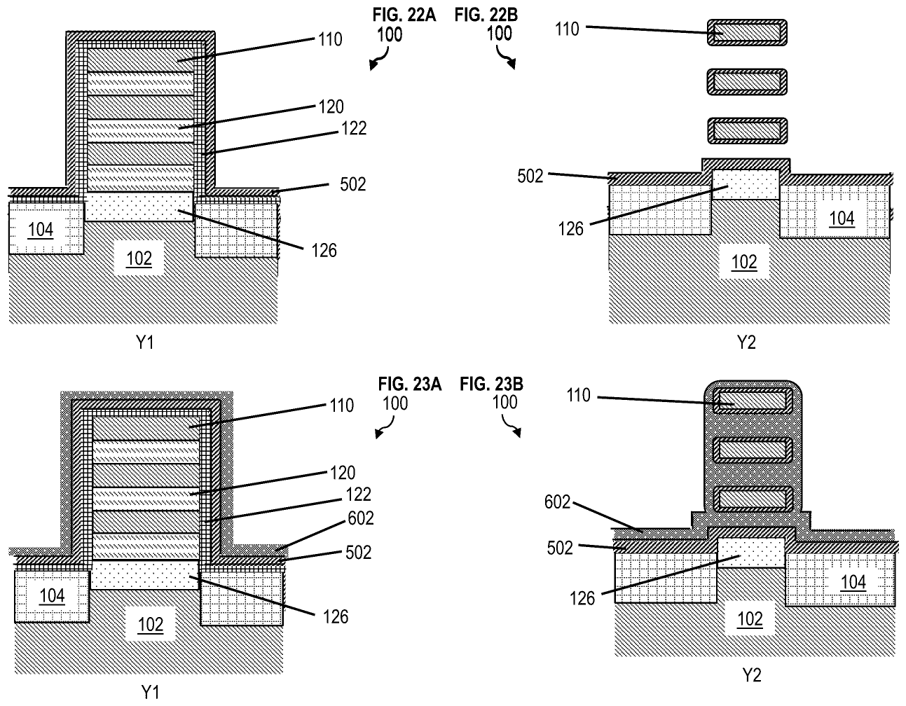

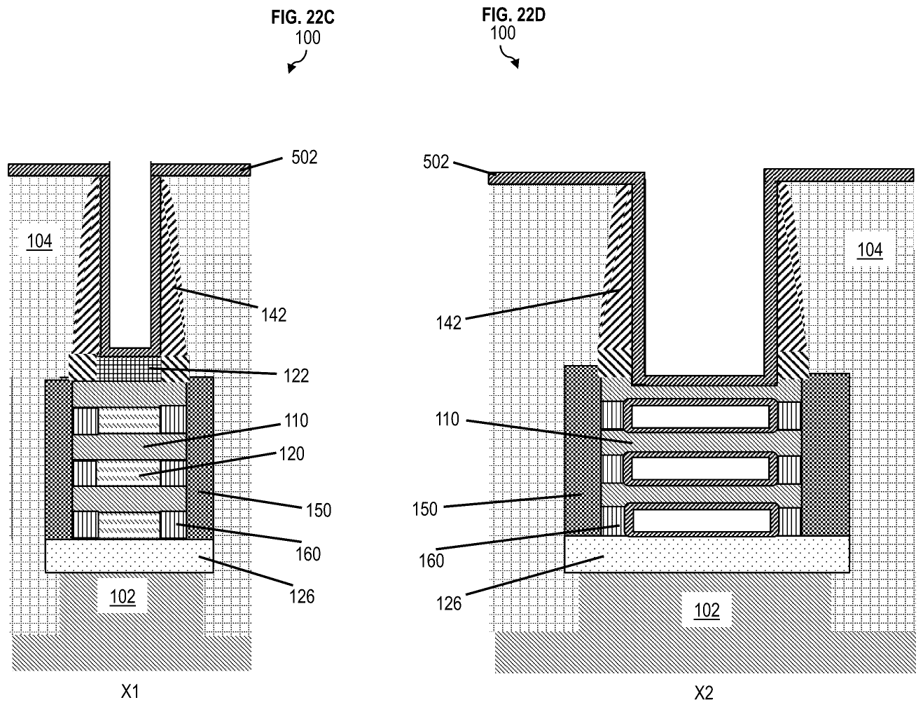

FIGS. 22A, 22B, 22C, and 22D depict the IC 100 after a nitridation treatment. A nitridation treatment is performed to convert the oxide layer 402 into a nitride layer 502 by infusing/implanting the oxide layer 402 with nitrogen atoms and then annealing, thereby resulting in the nitride layer 502. Moreover, the nitride layer 502 can be doped with nitrogen atoms.

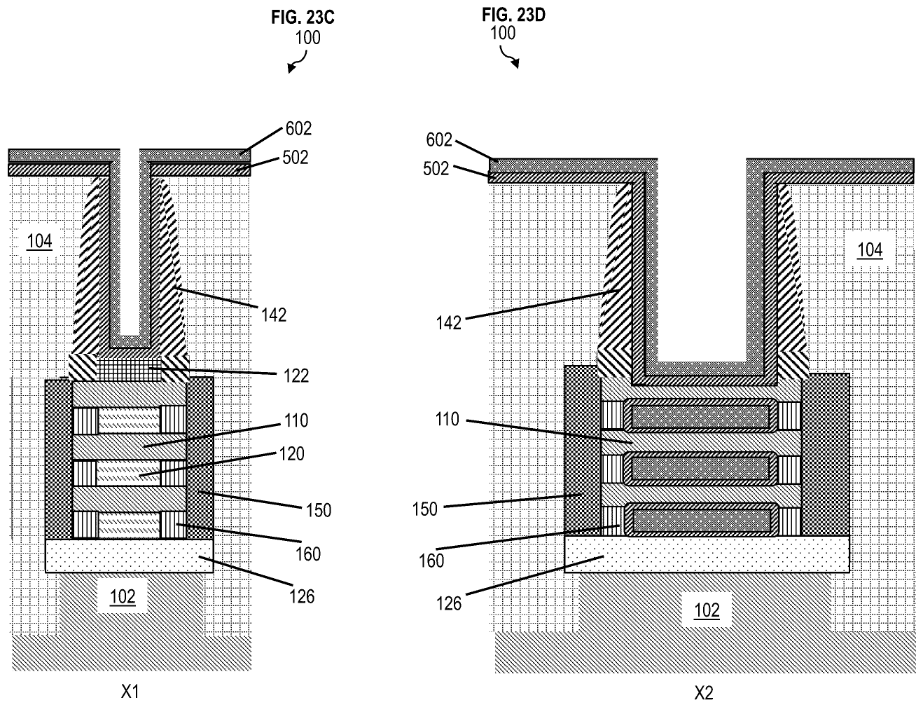

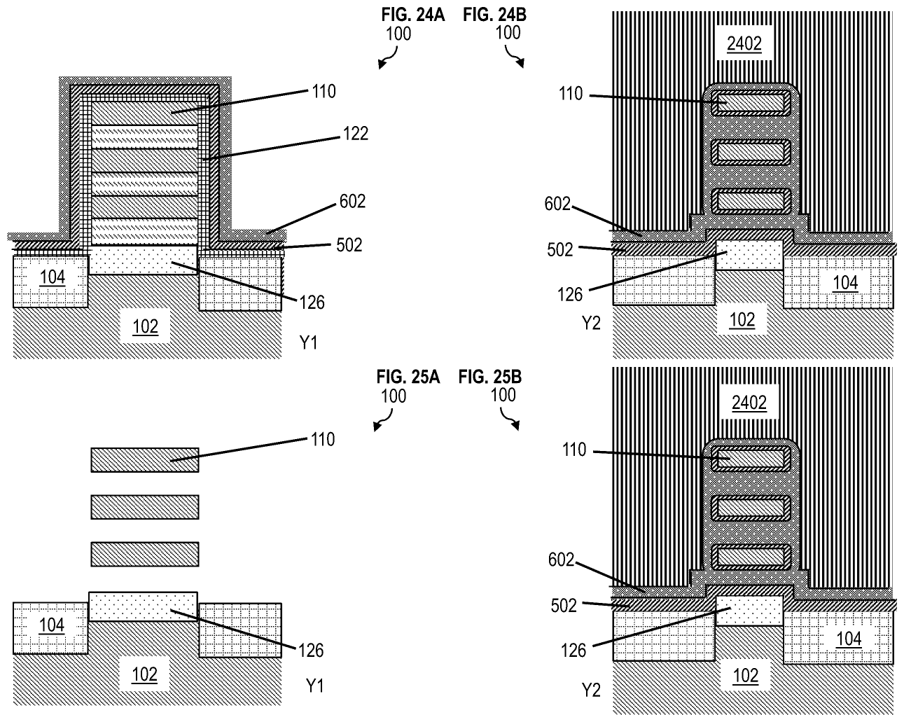

FIGS. 23A, 23B, 23C, and 23D depict the IC 100 after sacrificial layer deposition. A sacrificial layer 602 is deposited on the nitride layer 502. Example materials of the sacrificial layer 602 can include oxide materials, such as silicon dioxide, aluminum oxide, etc. The sacrificial layer 602 may be about 2 nm according to one or more embodiments.

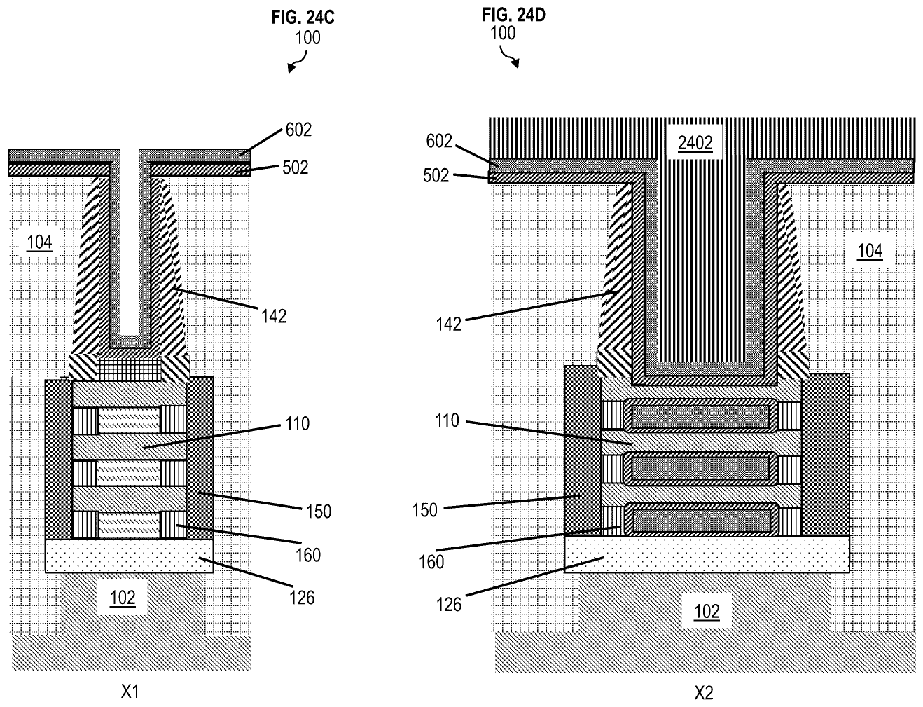

FIGS. 24A, 24B, 24C, and 24D depict the IC 100 after deposition of a block mask 2402. The block mask 2402 is deposited and patterned over the extended-gate transistor, while the standard-gate transistor is exposed.

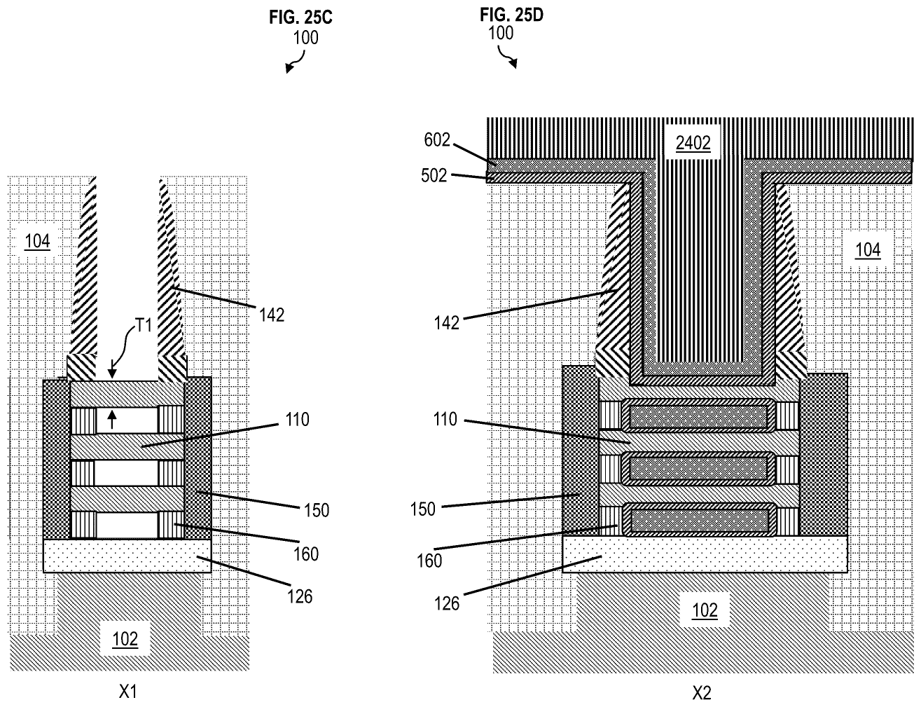

FIGS. 25A, 25B, 25C, and 25D depict the IC 100 after nanosheet release. Etching is performed to remove the sacrificial layer 602, the nitride layer 502, dummy oxide 122, and the sacrificial layers 120 in the standard-gate transistor. FIGS. 25A, 25B, 25C, and 25D correspond to FIGS. 12A, 12B, 12C, 12D, 12E, and 12F, where the block mask 2402 corresponds to block mask 1102. Subsequent fabrication processes follow the processes previously discussed in FIGS. 13-16, resulting in the standard-gate transistor 1620 and the extended-gate transistor 1622 depicted in FIGS. 16A, 16B, 16C, 16D, 16E, and 16F.

A method is provided for an extended-gate transistor and standard-gate transistor integration scheme with a dog bone structure for scaling on the IC 100. The method includes providing a first transistor (e.g., standard-gate transistor 1620) having first channel regions (e.g., of semiconductor layers 110), a high-k dielectric layer 1502 on the first channel regions, and gate material (e.g., gate structure 1602) on the high-k dielectric layer 1502. The method includes providing a second transistor (e.g., extended-gate transistor 1622) having second channel regions (e.g., of semiconductor layers 110), a nitride layer 502 on the second channel regions, the high-k dielectric layer 1502 on the nitride layer 502, and the gate material (e.g., gate structure 1602) on the high-k dielectric layer 1502, where the first and second channel regions comprise a corresponding number of semiconductor layers 110. For example, the standard-gate transistor 1620 and the extended-gate transistor 1622 have the same number of semiconductor layers 110 respectively forming the first and second channel regions.

In one or more embodiments, a first thickness H1 of the gate material between the first channel regions is greater than a second thickness H2 of the gate material between the second channel regions. For example, the thickness of the gate structure 1602 between the semiconductor layers 110 in the standard-gate transistor 1620 is greater than the thickness of the gate structure 1602 between the semiconductor layers 110 in the extended-gate transistor 1622.

The nitride layer surrounds the second channel regions but not the first channel regions. The gate material in the first transistor comprises a first width W1 in a first dimension, and the gate material in the second transistor comprises a second width W2 in the first dimension, the second width W2 being greater than the first width W1. The first transistor and the second transistor are on a bottom isolation layer 126. The nitride layer 502 of the second transistor is on a bottom isolation layer 126. The nitride layer 502 in the second transistor includes an oxide material with nitrogen atoms included. The nitrogen atoms can be infused, implanted, and/or doped in the oxide material. A bottom isolation layer 126 is under the first transistor and the second transistor. The high-k dielectric layer 1502 of the first transistor is on the bottom isolation layer 126 and the nitride layer 502 of the second transistor is on the bottom isolation layer 126, as depicted in FIGS. 16E and 16F.

According to one or more embodiments, a method is provided for an extended-gate transistor and standard-gate transistor integration scheme with a dog bone structure for scaling on the IC 100. The method includes forming an oxide layer 402 above first channel regions of a first transistor (e.g., standard-gate transistor 1620) and on second channel regions of a second transistor (e.g., extended-gate transistor 1622) and converting the oxide layer 402 to a nitride layer 502. The method includes removing the nitride layer 502 above the first channel regions of the first transistor (e.g., standard-gate transistor 1620) as depicted in FIGS. 8E and 25C, while the nitride layer 502 remains on the second channel regions of the second transistor (e.g., extended-gate transistor 1622) as depicted in FIGS. 8F and 25D. The method includes forming a high-k dielectric layer 1502 on the first channel regions of the first transistor (e.g., standard-gate transistor 1620) and on the nitride layer 502 on the second channel regions of the second transistor (e.g., extended-gate transistor 1622). The method includes forming gate material on the high-k dielectric layer 1502 of the first transistor and the second transistor, wherein the first and second channel regions comprise a corresponding number of semiconductor layers 110.

According to one or more embodiments, a first thickness of the gate material between the first channel regions is greater than a second thickness of the gate material between the second channel regions, and the second thickness of the gate material is reduced by an amount of the nitride layer formed between the second channel regions.

Gate material is formed around the semiconductor layers 110. The gate material includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Although not shown, contact formation and ILD formation are performed. ILD material can be deposited, source/drain contact openings are patterned by conventional lithography, and then metal is deposited to fill the cavities thereby forming metal contacts. A portion of the metal contacts may include silicide, resulting from the interface of the metal material and semiconductor material. The metal contacts are source/drain contacts that are respectively connected to epitaxial source/drain regions.

The ILD material can be SiO₂, SiN, a low-k dielectric material or an ultra-low-k dielectric material. Low-k dielectric materials may generally include dielectric materials having a k value of about 3.9 or less. The ultralow-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
a first transistor comprising first channel regions, a high-k dielectric layer on the first channel regions, and gate material on the high-k dielectric layer; and
a second transistor comprising second channel regions, a nitride layer on the second channel regions, the high-k dielectric layer on the nitride layer, and the gate material on the high-k dielectric layer, wherein the first and second channel regions comprise a corresponding number of semiconductor layers.

2. The semiconductor structure of claim 1, wherein a first thickness of the gate material between the first channel regions is greater than a second thickness of the gate material between the second channel regions.

3. The semiconductor structure of claim 1, wherein the nitride layer surrounds the second channel regions.

4. The semiconductor structure of claim 1, wherein:
the gate material in the first transistor comprises a first width in a first dimension; and
the gate material in the second transistor comprises a second width in the first dimension, the second width being greater than the first width.

5. The semiconductor structure of claim 1, wherein the first channel regions and the second channel regions have a trimmed middle section.

6. The semiconductor structure of claim 1, wherein the nitride layer surrounds the second channel regions.

7. The semiconductor structure of claim 1, wherein the nitride layer in the second transistor comprises an oxide material with nitrogen atoms included.

8. The semiconductor structure of claim 1, wherein a bottom isolation layer is under the first transistor and the second transistor.

9. The semiconductor structure of claim 8, wherein the high-k dielectric layer of the first transistor is on the bottom isolation layer and the nitride layer of the second transistor is on the bottom isolation layer.

10. A method comprising:
providing a first transistor comprising first channel regions, a high-k dielectric layer on the first channel regions, and gate material on the high-k dielectric layer; and
providing a second transistor comprising second channel regions, a nitride layer on the second channel regions, the high-k dielectric layer on the nitride layer, and the gate material on the high-k dielectric layer, wherein the first and second channel regions comprise a corresponding number of semiconductor layers.

11. The method of claim 10, wherein a first thickness of the gate material between the first channel regions is greater than a second thickness of the gate material between the second channel regions.

12. The method of claim 10, wherein the nitride layer surrounds the second channel regions.

13. The method of claim 10, wherein:
the gate material in the first transistor comprises a first width in a first dimension; and
the gate material in the second transistor comprises a second width in the first dimension, the second width being greater than the first width.

14. The method of claim 10, wherein the first channel regions and the second channel regions have a trimmed middle section.

15. The method of claim 10, wherein the nitride layer surrounds the second channel regions.

16. The method of claim 10, wherein the nitride layer in the second transistor comprises an oxide material with nitrogen atoms included.

17. The method of claim 10, wherein a bottom isolation layer is under the first transistor and the second transistor.

18. The method of claim 17, wherein the high-k dielectric layer of the first transistor is on the bottom isolation layer and the nitride layer of the second transistor is on the bottom isolation layer.

19. A method comprising:
forming an oxide layer above first channel regions of a first transistor and on second channel regions of a second transistor;
converting the oxide layer to a nitride layer;
removing the nitride layer above the first channel regions of the first transistor, while the nitride layer remains on the second channel regions of the second transistor;
forming a high-k dielectric layer on the first channel regions of the first transistor and on the nitride layer on the second channel regions of the second transistor; and
forming gate material on the high-k dielectric layer of the first transistor and the second transistor, wherein the first and second channel regions comprise a corresponding number of semiconductor layers.

20. The method of claim 19, wherein:
a first thickness of the gate material between the first channel regions is greater than a second thickness of the gate material between the second channel regions; and
the second thickness of the gate material is reduced by an amount of the nitride layer formed between the second channel regions.
